(19) United States
(12) Patent Application Publication
(10) Pub. No.: US 2024/0240082 A1
(43) Pub. Date: Jul. 18, 2024

(54) FLUORIDE PHOSPHOR, METHOD FOR MANUFACTURING SAME, AND LIGHT-EMITTING DEVICE

(71) Applicant: NICHIA CORPORATION, Anan-shi (JP)

(72) Inventors: Kenichi AOYAGI, Itano-gun (JP); Tomokazu YOSHIDA, Anan-shi (JP); Kazuya NISHIMATA, Anan-shi (JP)

(73) Assignee: NICHIA CORPORATION, Anan-shi (JP)

(21) Appl. No.: 18/565,503

(22) PCT Filed: May 26, 2022
(86) PCT No.: PCT/JP2022/021552

§ 371 Date: Nov. 29, 2023

(30) Foreign Application Priority Data
May 31, 2021 (JP) 2021-091754
Aug. 6, 2021 (JP) 2021-130074
Aug. 31, 2021 (JP) 2021-141629
May 23, 2022 (JP) 2022-083514

(51) Int. Cl. C09K 11/77; H01L 33/50

(52) U.S. Cl. CPC C09K 11/77348; H01L 33/502; H01L 2933/0041

(57) ABSTRACT

Provided is a fluoride phosphor that can improve reliability in a light-emitting device. The fluoride phosphor includes fluoride particles and an oxide covering at least a portion of the surface of the fluoride particles. The oxide contains at least one element selected from the group consisting of Si, Al, Ti, Zr, Sn, and Zn, and a content percentage of the oxide is in a range from 2 mass % to 30 mass %. The fluoride particles have a composition containing an element M including at least one element selected from the group consisting of Group 4 elements, Group 13 elements, and Group 14 elements, an alkali metal, Mn, and F, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

### TECHNICAL FIELD

The present disclosure relates to a fluoride phosphor, a method for manufacturing the fluoride phosphor, and a light-emitting device.

### BACKGROUND ART

Light-emitting devices in which a light-emitting element and a phosphor are combined are used in a wide range of fields, such as in illumination, on-board lighting, displays, and liquid crystal backlights. For example, a phosphor used in a light-emitting device in a liquid crystal backlight application is required to have high color purity, that is, the full width at half maximum of the emission peak must be narrow. A fluoride phosphor in which Mn is added is known as a red luminous phosphor having a narrow full width at half maximum of the emission peak.

For example, JP 2019-525974 T1 discloses that a manganese-doped red phosphor is coated with aluminum oxide or the like in order to reduce the issue of instability due to deterioration of the manganese-doped red phosphor, and further describes a light-emitting device provided with a fluorescent member containing the coated manganese-doped red phosphor and a resin.

### SUMMARY OF INVENTION

### Technical Problem

In a light-emitting device provided with a fluorescent member containing a fluoride phosphor and a resin, the reliability of the light-emitting device may decrease depending on the environment in which the light-emitting device is used. As such, an object of one aspect of the present disclosure is to provide a fluoride phosphor that can further improve the reliability of a light-emitting device, a method for manufacturing the fluoride phosphor, and a light-emitting device.

### Solution to Problem

A first aspect is a fluoride phosphor containing fluoride particles and an oxide covering at least a portion of the surface of the fluoride particle. The oxide contains at least one element selected from the group consisting of Si, Al, Ti, Zr, Sn, and Zn, and a content percentage of the oxide is in a range from 2 mass % to 30 mass % in relation to the fluoride phosphor. The fluoride particles have a composition containing an element M, an alkali metal, Mn, and F, the element including at least one element selected from the group consisting of Group 4 elements, Group 13 elements, and Group 14 elements, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

A second aspect is a method for manufacturing a fluoride phosphor, the manufacturing method including: preparing fluoride particles; and causing the prepared fluoride particles and a metal alkoxide including at least one element selected from the group consisting of Si, Al, Ti, Zr, Sn, and Zn to come into contact with each other in a liquid medium thereby covering at least a portion of the surface of the fluoride particle with an oxide derived from the metal alkoxide at an amount in a range from 2 mass % to 30 mass % relative to the fluoride phosphor. The fluoride particles have a composition containing an element M, an alkali metal, Mn, and F, the element M including at least one element selected from the group consisting of Group 4 elements, Group 13 elements, and Group 14 elements, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

A third aspect is a method for manufacturing a fluoride phosphor, the manufacturing method including: preparing fluoride particles; causing the prepared fluoride particles, rare earth ions including at least one type selected from the group consisting of La, Ce, Dy, and Gd, and phosphate ions to come into contact with each other in a liquid medium thereby obtaining fluoride particles to which a rare earth phosphate is adhered; and causing the fluoride particles to which the rare earth phosphate is adhered and a metal alkoxide including at least one element selected from the group consisting of Si, Al, Ti, Zr, Sn, and Zn to come into contact with each other in a liquid medium thereby covering at least a portion of the surface of the fluoride particle to which the rare earth phosphate is adhered with an oxide derived from the metal alkoxide at an amount in a range from 2 mass % to 30 mass % relative to the fluoride phosphor. The fluoride particles have a composition containing an element M, an alkali metal, Mn, and F, the element M including at least one element selected from the group consisting of Group 4 elements, Group 13 elements, and Group 14 elements, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

A fourth aspect is a light-emitting device provided with: a fluorescent member including the fluoride phosphor of the first aspect and a resin; and a light-emitting element having a light emission peak wavelength in a wavelength range from 380 nm to 485 nm.

### Advantageous Effects of Invention

According to one aspect of the present disclosure, a fluoride phosphor that can further improve the reliability of a light-emitting device, a method for manufacturing the fluoride phosphor, and a light-emitting device can be provided.

### BRIEF DESCRIPTION OF DRAWINGS

FIG. 1 is a schematic cross-sectional view illustrating one example of a light-emitting device containing a fluoride phosphor.

FIG. 2 is an example of a backscattered electron image of a fluoride phosphor obtained using a scanning electron microscope (SEM).

FIG. 3 is an example of a cross-sectional SEM image of a fluoride phosphor according to Example 6.

FIG. 4 is an example of an SEM image of the fluoride phosphor according to Example 6.

FIG. 5 is an example of a cross-sectional SEM image of a fluoride phosphor according to Example 8.

FIG. 6 is an example of an SEM image of the fluoride phosphor according to Example 8.

### DESCRIPTION OF EMBODIMENTS

The word “step” herein includes not only an independent step, but also a step that cannot be clearly distinguished from another step if the anticipated purpose of the step is achieved. If a plurality of substances applicable to a single component in a composition is present, the content of the single component in the composition means the total amount of the plurality of substances present in the composition, unless otherwise specified. Furthermore, with respect to an upper limit and a lower limit of numerical ranges described herein, the numerical values exemplified as the numerical range can be freely selected and combined. Note that herein, relationships such as the relationship between a color name and a chromaticity coordinate, the relationship between a wavelength range of light and a color name of monochromatic light are in accordance with JIS Z8110. The full width at half maximum of a phosphor means a wavelength width (full width at half maximum: FWHM) in an emission spectrum at which the emission intensity becomes 50% of the maximum emission intensity in the emission spectrum of the phosphor. The median size of the phosphor is the median size based on volume, and refers to the particle size corresponding to a volume accumulation of 50% from the small size side in a particle size distribution based on volume. The particle size distribution of the phosphor is measured by a laser diffraction method using a laser diffraction particle size distribution measuring device. Embodiments of the present invention will be described below in detail. The embodiments presented below exemplify a fluoride phosphor, a method for manufacturing the fluoride phosphor, and a light-emitting device, which all embody the technical concept of the present invention, but the present invention is not limited to the fluoride phosphor, the method for manufacturing the fluoride phosphor, or the light-emitting device presented below.

Fluoride Phosphor The fluoride phosphor may have fluoride particles and an oxide covering at least a portion of a surface of the fluoride particle. The oxide contains at least one element selected from the group consisting of silicon (Si), aluminum (Al), titanium (Ti), zirconium (Zr), tin (Sn), and zinc (Zn), and the content percentage of the oxide is in a range from 2 mass % to 30 mass % in relation to the fluoride phosphor. The fluoride particles have a composition containing an element M including at least one element selected from the group consisting of Group 4 elements, Group 13 elements, and Group 14 elements, an alkali metal, Mn, and F, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

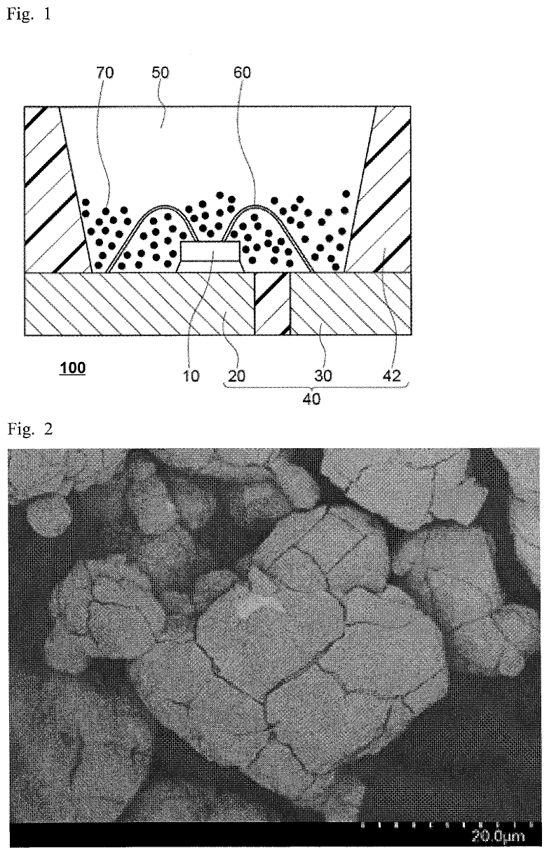

At least a portion of the surface of the fluoride particle having the specific composition is covered with a predetermined amount of a specific oxide, and thereby, for example, the moisture resistance is improved. Through this, the reliability of a light-emitting device provided with a fluorescent member containing a resin and the fluoride phosphor can be improved. For example, a decrease in the mass of the fluorescent member in a high temperature environment or a high humidity environment is suppressed. The decrease in the mass of the fluorescent member is thought to be mainly a decrease in the amount of the resin. It is conceivable that when the fluoride particles and the resin come into direct contact with each other in a high temperature environment or a high humidity environment, some sort of reaction occurs, and a decomposition product in which some interatomic bonds of the resin are broken is scattered. It is also conceivable that when the fluoride particles are covered with a predetermined amount of an oxide considered to have higher chemical stability than the fluoride particles, direct contact between the resin and the fluoride particles is suppressed, and thereby the reaction between the resin and the fluoride particles is suppressed, and the amount of the resin is maintained. It is also conceivable that since the resin also functions as a protective member for the phosphor, a decrease in the amount of the resin makes the phosphor more susceptible to the influence of the external environment including moisture, and accelerates the deterioration of the phosphor. In addition, when the amount of resin decreases, for example, the shape of the light-emitting surface of the fluorescent member in the light-emitting device illustrated in FIG. 1 is deformed, and as a result, the possibility of total reflection of light from the inside of the light-emitting device increases. Therefore, it is conceivable that the amount of light extracted to outside of the light-emitting device decreases, and the luminous flux of the light-emitting device decreases.

The fluoride particles contained in the fluoride phosphor may contain at least a fluorescent substance that is activated by Mn, or may consist of only a fluorescent substance that is activated by Mn. The composition of the fluoride particles is such that when the number of moles of the alkali metal is 2, the number of moles of Mn may be in a range greater than 0 and less than 0.2, and is preferably in a range from 0.01 to 0.12. The composition of the fluoride particles is also such that when the number of moles of the alkali metal is 2, the number of moles of the element M may be in a range greater than 0.8 and less than 1, and is preferably in a range from 0.88 to 0.99. The composition of the fluoride particles is also such that when the number of moles of the alkali metal is 2, the number of moles of F may be in a range greater than 5 and less than 7, and is preferably in a range from 5.9 to 6.1. The composition of the fluoride particles can be measured, for example, by inductively coupled plasma (ICP) emission spectroscopy.

The alkali metal in the composition of the fluoride particles may include at least one selected from the group consisting of lithium (Li), sodium (Na), potassium (K), rubidium (Rb), and cesium (Cs). The alkali metal may include at least potassium (K), and at least one selected from the group consisting of lithium (Li), sodium (Na), rubidium (Rb), and cesium (Cs). A ratio of the number of moles of K to the total number of moles of the alkali metal in the composition may be, for example, 0.90 or greater, and is preferably 0.95 or greater, or 0.97 or greater. The upper limit of the ratio of the number of moles of K may be, for example, 1 or less, or 0.995 or less. In the composition of the fluoride particles, some of the alkali metals may be substituted with ammonium ions (NH₄⁺). When some of the alkali metals are substituted with ammonium ions, the ratio of the number of moles of the ammonium ions to the total number of moles of the alkali metal in the composition may be, for example, 0.10 or less, and is preferably 0.05 or less, or 0.03 or less. The lower limit of the ratio of the number of moles of ammonium ions may be, for example, greater than 0, and may be preferably 0.005 or greater.

The element M in the composition of the fluoride particles includes at least one selected from the group consisting of Group 4 elements, Group 13 elements, and Group 14 elements. Examples of Group 4 elements include titanium (Ti), zirconium (Zr), and hafnium (Hf), and at least one selected from the group consisting of these elements may be included. Examples of Group 13 elements include boron (B), aluminum (Al), gallium (Ga), indium (In), and thallium (Tl), and at least one selected from the group consisting of these elements may be included. Examples of Group 14 elements include carbon (C), silicon (Si), germanium (Ge), and tin (Sn), and at least one selected from the group consisting of these elements may be included. The element M may include at least one of at least the Group 14 elements, may preferably include at least one of at least Si and Ge, and may more preferably include at least Si. In addition, the element M may include at least one of the Group 13 elements and at least one of the Group 14 elements, and preferably at least one of Al, Si, and Ge, and more preferably at least Al and Si.

A first composition, which is one aspect of the composition of the fluoride particles, may contain, as the element M, at least one selected from the group consisting of Group 4 elements and Group 14 elements, preferably at least one selected from the group consisting of Group 14 elements, and more preferably Si and/or Ge, and even more preferably at least Si. In addition, the first composition of the fluoride particles may have a total number of moles of Si, Ge, and Mn in a range from 0.9 to 1.1, preferably from 0.95 to 1.05, or from 0.97 to 1.03, per 2 μmoles of the alkali metal.

The first composition of the fluoride particles may be a composition represented by Formula (1) below:

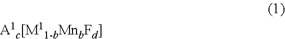

In Formula (1), A¹ may include at least one selected from the group consisting of Li, Na, K, Rb, and Cs. M¹ includes at least Si and/or Ge, and may further include at least one element selected from the group consisting of Group 4 elements and Group 14 elements; Mn may be a tetravalent Mn ion. Furthermore, b satisfies 0<b<0.2, c is an absolute value of the charge of the [M²_{1-b}Mn_{b}F_{d}] ion, and d satisfies 5<d<7.

A¹ in Formula (1) includes at least K, and may further include at least one selected from the group consisting of Li, Na, Rb, and Cs. Also, some of the A¹ may be substituted with ammonium ions (NH₄⁺). When some of the A¹ are substituted with ammonium ions, the ratio of the number of moles of the ammonium ions to the total number of moles of A¹ in the composition may be, for example, 0.10 or less, and preferably 0.05 or less or 0.03 or less. The lower limit of the ratio of the number of moles of ammonium ions may be, for example, greater than 0, and may be preferably 0.005 or greater.

In Formula (1), b is preferably in a range from 0.005 to 0.15, from 0.01 to 0.12, or from 0.015 to 0.1. Furthermore, c may be in a range from 1.8 to 2.2, and is preferably in a range from 1.9 to 2.1, or from 1.95 to 2.05. In addition, d may be in a range from 5.5 to 6.5, from 5.9 to 6.1, from 5.92 to 6.05, or from 5.95 to 6.025.

The fluoride particles of the first composition may have a first theoretical composition represented by Formula (1a) below:

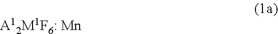

In Formula (1a), A¹ may include at least one selected from the group consisting of Li, Na, K, Rb, and Cs. M¹ includes at least Si and/or Ge, and may further include at least one element selected from the group consisting of Group 4 elements and Group 14 elements; Mn may be a tetravalent Mn ion.

A second composition, which is one aspect of the composition of the fluoride particles, may contain, as the element M, at least one selected from the group consisting of Group 4 elements and Group 14 elements and at least one Group 13 element, and preferably at least one selected from the group consisting of Group 14 elements and at least one Group 13 element, and more preferably at least Si and Al. In addition, the second composition of the fluoride particle may have a total number of moles of Si, Al, and Mn in a range from 0.9 to 1.1, preferably from 0.95 to 1.05, or from 0.97 to 1.03, per 2 moles of the alkali metal. Furthermore, the second composition of the fluoride particles may have a number of moles of Al in a range greater than 0 and 0.1, and preferably in a range greater than 0 and 0.03, from 0.002 to 0.02, or from 0.003 to 0.015, per 2 μmoles of the alkali metal.

The second composition of the fluoride particles may be a composition represented by Formula (2) below:

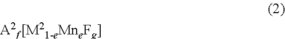

A² in Formula (2) includes at least K, and may further include at least one element selected from the group consisting of Li, Na, Rb, and Cs. M² includes at least Si and Al, and may further include at least one element selected from the group consisting of Group 4 elements, Group 13 elements, and Group 14 elements; Mn may be a tetravalent Mn ion. Furthermore, e satisfies 0<e<0.2, f is the absolute value of the charge of the [M²₁₋ₑMnₑF_{g}] ion, and g satisfies 5<g<7.

Also, some of the A² in Formula (2) may be substituted with ammonium ions (NH₄⁺). When some of the A² are substituted with ammonium ions, the ratio of the number of moles of the ammonium ions to the total number of moles of A² in the composition may be, for example, 0.10 or less, and is preferably 0.05 or less or 0.03 or less. The lower limit of the ratio of the number of moles of ammonium ions may be, for example, greater than 0, and may be preferably 0.005 or greater.

In Formula (2), e is preferably in a range from 0.005 to 0.15, from 0.01 to 0.12, or from 0.015 to 0.1. Furthermore, f may be, for example, in a range from 1.8 to 2.2, and is preferably in a range from 1.9 to 2.1, or from 1.95 to 2.05. In addition, g may be in a range from 5.5 to 6.5, from 5.9 to 6.1, from 5.92 to 6.05, or from 5.95 to 6.025.

Moreover, the fluoride particles of the second composition may have a second theoretical composition represented by Formula (2a) below:

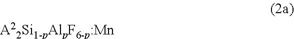

A² in Formula (2a) includes at least K, and may further include at least one element selected from the group consisting of Li, Na, Rb, and Cs. Here, p satisfies 0<p<1. Mn may be a tetravalent Mn ion.

The fluoride particles of the second composition may have protrusions, recessions, grooves, or the like in the surface of the particles. The state of the particle surface can be evaluated by, for example, measuring the angle of repose of a powder formed from the fluoride particles. The angle of repose of the powder formed from the fluoride particles having the second composition may be, for example, 70° or less, and is preferably 650 or less or 600 or less. The lower limit of the angle of repose is, for example, 30° or higher. The angle of repose is measured by, for example, an injection method.

When the fluoride particles having the second composition have protrusions, recessions, grooves, or the like in the surface thereof, and when the fluoride particles are covered with, for example, a predetermined amount of a specific oxide, the contact area between the fluoride particles and the oxide increases, and therefore, a strong bond is obtained between the fluoride particles and the oxide, and the fluoride particles can be coated with an oxide film that is not easily detached by an external force. In addition, in the step of covering the fluoride particles with a predetermined amount of a specific oxide, the fluoride particles can be covered with the predetermined amount of the oxide even in a case in which a relatively small amount of the oxide raw material is used. Similarly, in the case in which the surface of the fluoride particle is covered with a rare earth phosphate or a case in which an oxide covers the fluoride particle with a rare earth phosphate interposed therebetween, since the fluoride phosphor has protrusions, recessions, grooves, and the like in the surface, when the fluoride particle is covered with a predetermined amount of a specific rare earth phosphate, the contact area between the fluoride particle and the rare earth phosphate is increased, and therefore bonding between the fluoride particles and the rare earth phosphate is further strengthened, and the fluoride particles can be coated with a film of a rare earth phosphate that is not easily detached by an external force when a light-emitting device is manufactured. Further, in the step of covering the fluoride particles with the predetermined amount of the specific rare earth phosphate, even when a relatively small amount of the raw material of the rare earth phosphate is used, the fluoride particles can be covered with the predetermined amount of the rare earth phosphate.

From the perspective of improving luminance, the volume-based median size of the fluoride particles may be, for example, in a range from 5 μm to 90 μm, and is preferably in a range from 10 μm to 70 μm or from 15 μm to 50 μm. From the perspective of improving luminance, the particle size distribution of the fluoride particles may exhibit a single peak, and preferably exhibits a single peak with a narrow distribution range.

The fluoride phosphor may contain an oxide covering at least a portion of the surface of the fluoride particle. The oxide may cover the surface of the fluoride particle in a film shape, or may be disposed on the surface of the fluoride particle in the form of an oxide layer. Furthermore, the oxide film covering the surface of the fluoride particle is not limited to a state in which no cracks are present, and cracks may be present in a portion of the oxide film covering the surface of the fluoride particle as long as the effect of the present invention can be achieved. In addition, although the oxide film covering the surface of the fluoride particle preferably completely covers the entire surface thereof, a portion of the oxide film may be partially missing, and a portion of the surface of the fluoride particle may be exposed as long as the effect of the present invention can be achieved. The percentage of the fluoride particle covered by the oxide in the fluoride phosphor may be, for example, 50% or greater, preferably 80% or greater, or 90% or greater. The percentage of the fluoride particle covered by the oxide is calculated as the ratio of the surface area covered by the oxide to the surface area of the fluoride particle.

The oxide may contain at least one selected from the group consisting of Si, Al, Ti, Zr, Sn, and Zn. That is, the oxide may include at least one selected from the group consisting of silicon oxides (for example, SiOx, where x may be in a range from 1 to 2, preferably from 1.5 to 2, or approximately 2), aluminum oxides (for example, Al₂O₃), titanium oxides (for example, TiO₂), zirconium oxides (for example, ZrO₂), tin oxides (for example, SnO and SnO₂), and zinc oxides (for example, ZnO), and may include at least a silicon oxide. Only a single type of oxide may be included, or two or more types may be included.

The content percentage of the oxide in the fluoride phosphor may be in a range from 2 mass % to 30 mass %, and preferably from 5 mass % to 20 mass %, or from 8 mass % to 15 mass %, relative to the fluoride phosphor. Regarding the content percentage of the oxide in the fluoride phosphor, when the oxide is a silicon oxide for example, the amounts of each constituent element contained in the fluoride particles covered by the oxide and in the fluoride phosphor not containing the oxide are analyzed by inductively coupled plasma (ICP) emission spectrometry, and the molar ratios of the respective constituent elements are calculated such that the number of moles of the alkali metal is 2. The difference in the molar ratios of silicon before and after covering with the oxide is converted to the mass of silicon oxide (for example, SiO₂), and the content percentage of the silicon oxide (for example, SiO₂) is calculated with the mass of the fluoride particles (fluoride phosphor) covered with the oxide being 100 mass %. The reliability of the light-emitting device can be further improved by setting the content percentage of the oxide to within the above range.

In the fluoride phosphor, the fluoride particles may be covered with an oxide layer. The average thickness of the oxide layer covering the fluoride particles may be, for example, in a range from 0.1 μm to 1.8 μm, and is preferably in a range from 0.15 μm to 1.0 μm, or from 0.20 μm to 0.8 μm. The average thickness of the oxide layer in the fluoride phosphor may be, for example, an actually measured average thickness determined by actually measuring the thickness of a layer identified as an oxide layer at several positions in a cross-sectional image of the fluoride phosphor and then calculating the arithmetic mean thereof. The average thickness of the oxide layer in the fluoride phosphor may be a below-described theoretical thickness calculated from the intensity ratio of Kα rays of the element F. The theoretical thickness can be calculated from a ratio of a peak intensity of Kα rays of the element F in the fluoride phosphor covered with an oxide to a peak intensity of Kα rays of the element F in the fluoride particles not covered with an oxide layer, using a database from The Center for X-Ray Optics (CXRO). The theoretical thickness is calculated as a value calculated by averaging presence of defects such as cracks and chippings in the oxide layer.

In the fluoride phosphor, the fluoride particles are covered with an oxide, and therefore the peak intensity of characteristic X-rays derived from the fluoride particles decreases in accordance with the amount of the oxide covering the fluoride particles. Therefore, in the fluoride phosphor, the state of coverage by the oxide can be evaluated by evaluating the peak intensity of the characteristic X-rays derived from the fluoride particles. Specifically, in X-ray fluorescence (XRF) elemental analysis, the ratio of the peak intensity of Kα rays of the element F in the fluoride phosphor to the peak intensity of the Kα rays of the element F in the fluoride particles may be, for example, 80% or less, and is preferably 70% or less, or 60% or less. The lower limit value of the ratio of the peak intensities may be, for example, 20% or greater. The reliability of the light-emitting device can be more effectively improved by setting the ratio of the peak intensity of the Kα rays of the element F in the fluoride phosphor to within the above range.

In the fluoride phosphor, the rare earth phosphate may be disposed on the surfaces of the fluoride particles, and the oxide may cover the fluoride particles with the rare earth phosphate interposed therebetween. Through this, moisture and heat resistance of the fluoride phosphor tend to improve. In addition, the adhesiveness of the oxide to the fluoride particles is improved, and coatability by the oxide tends to further improve. The rare earth phosphate disposed on the surface of the fluoride particles may be adhered as particles to the surface of the fluoride particles, or may cover the surface of the fluoride particles as a film or a layer. The rare earth phosphate may be preferably adhered as particles to the surfaces of the fluoride particles.

The rare earth phosphate may contain at least one rare earth element selected from the group consisting of lanthanum (La), cerium (Ce), dysprosium (Dy) and gadolinium (Gd), and preferably at least lanthanum.

As a content percentage of rare earth elements, the content percentage of the rare earth phosphate in the fluoride phosphor may be, for example, in a range from 0.1 mass % to 20 mass %, and preferably in a range from 0.2 mass % to 15 mass %, or from 0.3 mass % to 10 mass %.

The surface of the fluoride phosphor may be further treated with a coupling agent. That is, a surface treatment layer containing a functional group derived from a coupling agent may be disposed on the surface of the fluoride phosphor. By disposing the surface treatment layer on the surface of the fluoride phosphor, for example, the moisture resistance of the fluoride phosphor is further improved.

Examples of the functional group derived from the coupling agent include a silyl group having an aliphatic group with from 1 to 20 carbons, and preferably a silyl group having an aliphatic group with from 6 to 12 carbons. For the functional group derived from the coupling agent, only a single type may be used, or a combination of two or more types may be used.

Examples of the coupling agent include a silane coupling agent, a titanium coupling agent, and an aluminum coupling agent. Examples of the silane coupling agent include alkyl trialkoxysilanes, such as methyl trimethoxysilane, ethyl trimethoxysilane, propyl trimethoxysilane, hexyl trimethoxysilane, octyl trimethoxysilane, decyl trimethoxysilane, and decyl triethylsilane; aryl trialkoxysilanes, such as phenyl trimethoxysilane, and styryl trimethoxysilane; vinyl trialkoxysilanes, such as vinyl trimethoxysilane; aminoalkyl trialkoxysilanes, such as 3-aminopropyl triethoxysilane; and glycidoxyalkyl trialkoxysilanes, such as 3-glycidoxypropyl trimethoxysilane, and the silane coupling agent may be at least one selected from the group consisting of these. From the perspective of being able to procure the coupling agent relatively easily, the coupling agent is preferably a silane coupling agent.

In one aspect, the fluoride phosphor may include fluoride particles and a rare earth phosphate disposed on at least a portion of the surface of the fluoride particle. In addition, in the fluoride phosphor having the rare earth phosphate disposed on at least a portion of the surface of the fluoride particle, a surface treatment layer containing a functional group derived from a coupling agent may be further disposed on the surfaces of the fluoride particles. Disposing the rare earth phosphate on the surface of the fluoride particles improves, for example, the moisture resistance of the fluoride phosphor. Through this, the reliability of a light-emitting device provided with a fluorescent member containing a resin and the fluoride phosphor can be improved. Also, for example, a decrease in the mass of the fluorescent member in a high temperature environment or a high humidity environment is suppressed. Furthermore, when the fluoride phosphor having the rare earth phosphate disposed on at least a portion of the surface of the fluoride particle also has the surface treatment layer containing a functional group derived from a coupling agent on the surface of the fluoride particle, the interfacial energy between the surface-treated fluoride phosphor and a sealing resin such as a silicone resin is reduced, and thus the fluoride phosphor is easily mixed and dispersed uniformly in the sealing resin. Furthermore, when the mixture thereof is poured into a package of a light-emitting device and allowed to stand, the fluoride phosphor can be sedimented densely and uniformly on a light-emitting element (for example, an LED chip). Therefore, the temperature of the fluoride phosphor can be kept low when the light-emitting device is driven, and as a result, a light-emitting device having high luminous efficiency and high reliability can be obtained.

From the perspective of improving luminance, a volume-based median size of the fluoride phosphor may be, for example, in a range from 10 μm to 90 μm, and is preferably in a range from 15 μm to 70 m or from 20 μm to 50 μm. From the perspective of improving luminance, the particle size distribution of the fluoride phosphor may have a single peak, and preferably have a single peak with a narrow distribution range.

The fluoride phosphor is, for example, a phosphor activated by a tetravalent manganese ion, and the fluoride phosphor absorbs light of a short wavelength range of visible light and emits red light. The excitation light may be primarily light in the blue region, and the peak wavelength of the excitation light may be, for example, within a wavelength range of from 380 nm to 485 nm. The emission peak wavelength in the emission spectrum of the fluoride phosphor may be, for example, within a wavelength range from 610 nm to 650 nm. The full width at half maximum in the emission spectrum of the fluoride phosphor may be, for example, 10 nm or less.

In a case in which the fluoride particles constituting the fluoride phosphor have the second composition, the fluoride phosphor may have protrusions, recessions, grooves, or the like in the surface of the particles. The angle of repose of a powder formed from the fluoride phosphor containing the fluoride particles having the second composition may be, for example, 700 or less, and is preferably 65° or less or 60° or less. The lower limit of the angle of repose is, for example, 30° or higher. The angle of repose is measured by, for example, an injection method.

The fluoride phosphor obtained by coating the fluoride particles having the second composition with the oxide and/or the rare earth phosphate may have protrusions, recessions, grooves, or the like in the surface thereof, even after being coated with the oxide and/or the rare earth phosphate. As a result, the contact area between the powder of the fluoride phosphor is reduced due to the protrusions, recessions, and grooves in the surface of the fluoride phosphor, and thereby aggregation of the powder is suppressed. Therefore, the particles of the fluoride phosphor particles can be more uniformly dispersed in a resin composition when manufacturing a light-emitting device. In addition, for example, in a case in which a dispenser is used when manufacturing a light-emitting device, issues such as the needle of the dispenser becoming clogged with the fluoride phosphor are less likely to occur. In addition, a light-emitting device in which aggregation of the fluoride phosphor particles is minimal and variation in chromaticity is small can be obtained.

### Method for Manufacturing Fluoride Phosphor

A first aspect of a method for manufacturing a fluoride phosphor (hereinafter, also referred to as a first manufacturing method) includes a preparation step of preparing fluoride particles, and a synthesizing step of causing the prepared fluoride particles and a metal alkoxide containing at least one element selected from the group consisting of Si, Al, Ti, Zr, Sn, and Zn to come into contact with each other in a liquid medium thereby covering the fluoride particles with an oxide derived from the metal alkoxide. In the first manufacturing method, the coverage amount of the oxide may be in a range from 2 mass % to 30 mass % in relation to the fluoride phosphor. In addition, the prepared fluoride particles have a composition containing an element M including at least one element selected from the group consisting of Group 4 elements, Group 13 elements, and Group 14 elements, an alkali metal, Mn, and F, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

By causing the fluoride phosphor having the predetermined composition to come into contact with the metal alkoxide in a liquid medium, a fluoride phosphor in which at least a portion of the surface of the fluoride particle is covered with an oxide derived from the metal alkoxide can be efficiently produced. In a light-emitting device provided with a fluorescent member containing the obtained fluoride phosphor and a resin, reliability in a high temperature environment, for example, is improved.

In the preparation step, fluoride particles having a predetermined composition are prepared. In the preparation step, the fluoride particles may be purchased, or the desired fluoride particles may be manufactured. Note that the details of the prepared fluoride particles are as described above.

For example, the fluoride particles can be manufactured as follows. In a case in which the fluoride particles have a first composition, for example, the fluoride particles can be manufactured by a manufacturing method including a step of mixing a solution a and a solution b, the solution a containing at least hydrogen fluoride, a first complex ion including tetravalent manganese, and a second complex ion including a fluorine ion and at least one element selected from the group consisting of Group 4 elements and Group 14 elements, and the solution b containing at least hydrogen fluoride and an alkali metal including at least potassium.

The fluoride particle can also be manufactured by a manufacturing method including a step of mixing a first solution, a second solution, and a third solution, in which the first solution contains at least hydrogen fluoride and a first complex ion including tetravalent manganese, the second solution contains at least hydrogen fluoride and an alkali metal including at least potassium, and the third solution contains at least a second complex ion including a fluorine ion and at least one selected from the group consisting of Group 4 elements and Group 14 elements.

In a case in which the fluoride particles have a second composition, the fluoride particles having the second composition can be manufactured by, for example, a manufacturing method including: preparing fluoride particles having the first composition; preparing fluoride particles containing Al, an alkali metal, and F; and carrying out a first heat treatment step of subjecting a mixture of the fluoride particles having the first composition and the fluoride particles containing Al, an alkali metal, and F to a first heat treatment in an inert gas atmosphere at a temperature in a range from 600° C. to 780° C. Here, the composition of the fluoride particles containing Al, an alkali metal, and F may be such that the ratio of the total number of moles of the alkali metal per mole of Al is in a range from 1 to 3, and the ratio of the number of moles of F per mole of Al is in a range from 4 to 6. Alternatively, the ratio of the total number of moles of the alkali metal per mole of Al may be in a range from 2 to 3, and the ratio of the number of moles of F per mole of Al may be in a range from 5 to 6.

The method for manufacturing the fluoride phosphor may further include a second heat treatment step in which, subsequent to the first heat treatment, the obtained first heat-treated product is subjected to a second heat treatment at a second heat treatment temperature of 400° C. or higher to obtain a second heat-treated product.

The second heat treatment step may be implemented only with the fluoride particles, or the second heat treatment step may be implemented with the fluoride particles and a fluorine-containing substance. The fluorine-containing substance may be in a solid state, a liquid state, or a gaseous state at normal temperature. An example of a fluorine-containing substance that is in a solid or liquid state is NH₄F. Also, examples of fluorine-containing substances that are in a gaseous state include F₂, CHF₃, CF₄, NH₄HF₂, HF, SiF₄, KrF₄, XeF₂, XeF₄, and NF₃. The fluorine-containing substance that is in a gaseous state may be at least one selected from the group consisting of these, and is preferably at least one selected from the group consisting of F₂ and HF.

The second heat treatment temperature is preferably higher than 400° C., and may be 425° C. or higher, 450° C. or higher, or 480° C. or higher. The upper limit of the second heat treatment temperature may be, for example, less than 600° C., preferably lower than 580° C. such as 550° C. or lower or 520° C. or lower. The second heat treatment temperature may be a temperature lower than the first heat treatment temperature.

It is thought that the fluoride particles of the second composition synthesized by the solid-phase reaction method in the first heat treatment step are in a state of containing a compound having a so-called mixed valence because tetravalent Si ions, trivalent Al ions, and tetravalent Mn ions are present at the same positions in the crystals of the fluoride particles. Thus, it is thought that vacancies exist at positions where fluorine ions should exist in the crystal in proportion to the abundance ratio of the tetravalent Si ions, the trivalent Al ions, and the tetravalent Mn ions in order to compensate for the deficient charge of all cations having mixed valences.

Here, as disclosed in JP 2010-254933 A for example, in fluoride particles synthesized by the liquid-phase reaction method, a large number of hydroxide ions introduced into the crystal from the hydroxide ions present in the solution are present in a mixed manner with fluorine ions at positions where fluorine ions should be present in the crystals, and it is thought that the hydroxide ions cause a loss of stability of the fluoride particles. Meanwhile, a solution in which hydroxide ions can be present is not used in the fluoride particles of the second composition synthesized by the solid-phase reaction method through heat treatment, and therefore hydroxide ions that cause a loss of stability of the fluoride particles are not present in a mixed manner.

In addition, in the fluoride particles having the second composition and synthesized by the solid-phase reaction method through the first heat treatment, manganese ions having different valences are present in a mixed manner in the crystals or on the crystal surfaces of the fluoride particles. In a case in which Mn ions having different valences are present in a mixed manner in the fluoride particles, the valences of the Mn ions can be uniformly set to a tetravalent state by further subjecting to a heat treatment in a state in which the fluoride particles are in contact with a fluorine-containing substance, and thus the luminous efficiency of the fluoride particles can be increased.

In the synthesizing step, the prepared fluoride particles and a metal alkoxide containing at least one element selected from the group consisting of Si, Al, Ti, Zr, Sn, and Zn are brought into contact with each other in a liquid medium thereby covering the fluoride particles with an oxide derived from the metal alkoxide, and hence a fluoride phosphor is obtained. An oxide derived from the metal alkoxide can be produced by solvolysis of the metal alkoxide, and a fluoride phosphor containing fluoride particles covered by the produced oxide is obtained.

An aliphatic group of the alkoxide constituting the metal alkoxide may have a number of carbons, for example, in a range from 1 to 6, preferably from 1 to 4, or from 1 to 3. The oxide may include at least one element selected from the group consisting of Si, Al, Ti, Zr, Sn, and Zn. For each of the metal and the aliphatic group contained in the metal alkoxide, only a single type may be used alone, or two or more types may be used in combination.

Specific examples of the metal alkoxide include tetramethoxy silane, tetraethoxy silane, tetraisopropoxy silane, trimethoxy aluminum, triethoxy aluminum, triisopropoxy aluminum, tetramethoxy titanium, tetraethoxy titanium, tetraisopropoxy titanium, tetramethoxy zirconium, tetraethoxy zirconium, tetraisopropoxy zirconium, tetraethoxy tin, dimethoxy zinc, and diethoxy zinc. The metal alkoxide is preferably at least one selected from the group consisting of these, and is more preferably at least one selected from the group consisting of tetramethoxy silane, tetraethoxy silane, and tetraisopropoxy silane. For metal alkoxide in the synthesizing step, only a single type may be used alone, or two or more types may be used in combination.

As an addition amount in terms of oxide, the addition amount of the metal alkoxide used in the synthesizing step may be, for example, in a range from 2 mass % to 30 mass %, and preferably 5 mass % or greater or 8 mass % or greater, and preferably 25 mass % or less or 20 mass % or less, relative to the total mass of the fluoride particles. As an addition amount of the metal alkoxide, the addition amount of the metal alkoxide used in the synthesizing step may be, for example, in a range from 5 mass % to 110 mass %, and preferably 15 mass % or greater or 25 mass % or greater, and preferably 90 mass % or less or 75 mass % or less, relative to the total mass of the fluoride particles.

Contact between the fluoride particles and the metal alkoxide is carried out in a liquid medium. Examples of the liquid medium include water; alcohol-based solvents such as methanol, ethanol, and isopropyl alcohol; nitrile-based solvents such as acetonitrile; and hydrocarbon-based solvents such as hexane. The liquid medium may contain at least water and an alcohol-based solvent. When the liquid medium contains an alcohol-based solvent, the content of the alcohol-based solvent in the liquid medium may be, for example, 60 mass % or greater, and preferably 70 mass % or greater. Furthermore, the content of water in the liquid medium may be, for example, in a range from 4 mass % to 40 mass %.

The liquid medium may further contain a pH adjusting agent. Examples of the pH adjusting agent include an alkaline substance such as ammonia, sodium hydroxide, and potassium hydroxide, and an acidic substance such as hydrochloric acid, nitric acid, sulfuric acid, and acetic acid. When the liquid medium contains a pH adjusting agent, in acidic conditions, the pH of the liquid medium may be, for example, in a range from 1 to 6, and preferably from 2 to 5. In alkaline conditions, the pH of the liquid medium may be in a range from 8 to 12, and preferably from 8 to 11.

The mass ratio of the liquid medium to the fluoride particles may be, for example, in a range from 100 mass % to 1000 mass %, preferably 150 mass % or higher or 180 mass % or higher, and preferably 600 mass % or lower or 300 mass % or lower. When the mass ratio of the liquid medium is within the range described above, the fluoride particles tend to be more uniformly covered with oxides.

Contact between the fluoride particles and the metal alkoxide can be implemented by, for example, adding the metal alkoxide to a suspension containing the fluoride particles. As necessary, stirring or the like may be performed at that time. Furthermore, the contact temperature of the fluoride particles and the metal alkoxide may be, for example, in a range from 0° C. to 70° C., and preferably from 10° C. to 40° C. The contact time may be, for example, in a range from 1 hour to 12 hours. Note that the time required for addition of the metal alkoxide is also included in the contact time.

A second aspect of the method for manufacturing a fluoride phosphor (hereinafter, also referred to as a second manufacturing method) includes: a preparation step in which fluoride particles are prepared; an adherence step in which the prepared fluoride particles, rare earth ions including at least one lanthanoid selected from the group consisting of La, Ce, Dy, and Gd, and phosphate ions are brought into contact in a liquid medium to obtain fluoride particles to which rare earth phosphate is adhered; and a synthesizing step in which the fluoride particles to which the rare earth phosphate is adhered are brought into contact with a solution containing a metal alkoxide including at least one element selected from the group consisting of Si, Al, Ti, Zr, Sn, and Zn to thereby cover the fluoride particles to which the rare earth phosphate is adhered with an oxide derived from the metal alkoxide. In the second manufacturing method, the coverage amount of the oxide may be in a range from 2 mass % to 30 mass % in relation to the fluoride phosphor. In addition, the prepared fluoride particles may have a composition containing an element M including at least one element selected from the group consisting of Group 4 elements, Group 13 elements, and Group 14 elements, an alkali metal, Mn, and F, and when the number of moles of the alkali metal is 2, the number of moles of Mn is in a range greater than 0 and less than 0.2, the number of moles of the element M is a range greater than 0.8 and less than 1, and the number of moles of F is in a range greater than 5 and less than 7.

In the second manufacturing method, after the rare earth phosphate is adhered to the surface of the fluoride particles, the fluoride particles to which the rare earth phosphate is adhered are covered with the oxide derived from the metal alkoxide, and thereby the moisture and heat resistance of the resultant fluoride phosphor tends to be further improved.

The preparation step in the second manufacturing method is the same as the preparation step in the first manufacturing method. In addition, the synthesizing step in the second manufacturing method is the same as the synthesizing step in the first manufacturing method with the exception that the rare earth phosphate is adhered to the fluoride particles subjected to the synthesizing step.

In the adherence step, the prepared fluoride particles, the rare earth ions, and the phosphate ions are brought into contact in a liquid medium. Through this, the rare earth phosphate is adhered to the surfaces of the fluoride particles, and fluoride particles on which the rare earth phosphate is adhered are obtained. It is thought that by adhering a rare earth phosphate to the fluoride particles in a liquid medium, for example, the rare earth phosphate is adhered more uniformly to the surface of the fluoride particles.

The liquid medium need only be one that can dissolve the phosphate ions and the rare earth ions, and preferably contains at least water from the viewpoint of easily dissolving these ions. As necessary, the liquid medium may further include a reducing agent such as hydrogen peroxide, an organic solvent, a pH adjusting agent, and the like. Examples of the organic solvent that can be contained in the liquid medium include alcohols such as ethanol and isopropanol. Examples of the pH adjusting agent include basic compounds such as ammonia, sodium hydroxide, and potassium hydroxide, and acidic compounds such as hydrochloric acid, nitric acid, sulfuric acid, and acetic acid. When the liquid medium contains a pH adjusting agent, the pH of the liquid medium is, for example, in a range from 1 to 6, and preferably from 1.5 to 4. When the pH is equal to or higher than the lower limit value described above, a sufficient adherence amount of the rare earth phosphate tends to be produced, and when the pH is equal to or less than the upper limit value described above, a decrease in the emission characteristics of the fluoride phosphor tends to be suppressed. When the liquid medium contains water, the content percentage of the water in the liquid medium may be, for example, 70 mass % or greater, 80 mass % or greater, and preferably 90 mass % or greater.

The mass ratio of the liquid medium to the fluoride particles is, for example, 100 mass % or greater or 200 mass % or greater and is, for example, 1000 mass % or less or 800 mass % or less. When the mass ratio of the liquid medium is equal to or greater than the above-described lower limit value, more uniform adherence of the rare earth phosphate to the surfaces of the fluoride particles is facilitated, and when the mass ratio of the liquid medium is equal to or less than the above-described upper limit value, the adherence rate of the rare earth phosphate to the fluoride particles tends to further improve.

The liquid medium preferably contains phosphate ions, and more preferably contains water and phosphate ions. In a case in which the liquid medium contains phosphate ions, the prepared fluoride particles and the liquid medium are mixed, and then further mixed with a solution containing the rare earth ions, and thereby the phosphate ions and the rare earth ions can be brought into contact in the liquid medium containing the fluoride particles. In a case in which the liquid medium contains phosphate ions, the phosphate ion concentration in the liquid medium is, for example, 0.05 mass % or higher, preferably 0.1 mass % or higher, and, for example, 5 mass % or lower, and preferably 3 mass % or lower. When the phosphate ion concentration in the liquid medium is greater than or equal to the lower limit described above, the amount of the liquid medium is not excessive, elution of the composition components from the fluoride particles is suppressed, and the characteristics of the fluoride phosphor tend to be favorably maintained. When the phosphate ion concentration is less than or equal to the upper limit described above, uniformity of matter adhered on the fluoride particles tends to be favorable.

Phosphate ions include ortho-phosphate ions, polyphosphate (meta-phosphate) ions, phosphite ions, and hypophosphite ions. Polyphosphate ions include polyphosphate ions having a linear structure, such as pyrophosphate ions and tripolyphosphate ions, and cyclic polyphosphate ions, such as hexa-meta-phosphate ions.

In a case in which the liquid medium contains phosphate ions, a compound that serves as a source of phosphate ions may be dissolved in the liquid medium to prepare the liquid medium containing phosphate ions, or a solution containing a phosphate ion source may be mixed with the liquid medium to prepare the liquid medium containing phosphate ions. Examples of the phosphate ion source include: phosphoric acid; meta-phosphoric acid; alkali metal phosphates such as sodium phosphate and potassium phosphate; alkali metal hydrogen phosphates such as sodium hydrogen phosphate and potassium hydrogen phosphate; alkali metal dihydrogen phosphates such as sodium dihydrogen phosphate and potassium dihydrogen phosphate; alkali metal hexa-meta-phosphates such as sodium hexa-meta-phosphate and potassium hexa-meta-phosphate; alkali metal pyrophosphates such as sodium pyrophosphate and potassium pyrophosphate; and ammonium phosphates such as ammonium phosphate.

The liquid medium preferably contains a reducing agent, more preferably contains water and a reducing agent, and even more preferably contains water, phosphate ions, and a reducing agent. When the liquid medium contains a reducing agent, precipitation of manganese dioxide or the like derived from manganese contained in the fluoride particles can be effectively suppressed. The reducing agent contained in the liquid medium is preferably one which, for example, can reduce tetravalent manganese ions eluted from the fluoride into the liquid medium, and examples include hydrogen peroxide, oxalic acid, and hydroxylamine hydrochloride. Of these, hydrogen peroxide decomposes in water and thus does not adversely affect fluoride, and therefore hydrogen peroxide is preferable.

In a case in which the liquid medium contains a reducing agent, a compound that serves as a reducing agent may be dissolved in the liquid medium to prepare the liquid medium containing a reducing agent, or a solution containing a reducing agent may be mixed with the liquid medium to prepare the liquid medium containing a reducing agent. The content of the reducing agent in the liquid medium is not particularly limited, but for example, the content may be 0.1 mass % or higher, and preferably 0.3 mass % or higher.

Examples of rare earth elements that become rare earth ions that contact the phosphate ions include, in addition to Sc and Y, lanthanoids including La, Ce, Pr, Nd, Pm, Sm, Eu, Gd, Tb, Dy, Ho, Er, Tm, Yb, and Lu, and the rare earth element is preferably at least one selected from the lanthanoids, and more preferably at least one selected from the group consisting of La, Ce, Dy, and Gd.

Contact between the phosphate ions and the rare earth ions in the liquid medium may be caused, for example by dissolving a compound that serves as a rare earth ion source in a liquid medium containing phosphate ions, or by mixing a liquid medium containing phosphate ions with a solution containing rare earth ions. The solution containing rare earth ions can be prepared, for example, by dissolving a compound that serves as a rare earth ion source in a solvent such as water. The compound that serves as a rare earth ion source is, for example, a metal salt containing a rare earth element, and examples of the anion constituting the metal salt include nitrate ions, sulfate ions, acetate ions, and chloride ions.

Contact between the phosphate ions and the rare earth ions in the liquid medium can include, for example, obtaining a phosphor slurry by mixing fluoride particles with a liquid medium containing phosphate ions and preferably further containing a reducing agent, and mixing the phosphor slurry with a solution containing rare earth ions.

In the liquid medium in which the phosphate ions and the rare earth ions are in contact, the content percentage of the rare earth ions is, for example, 0.05 mass % or greater or 0.1 mass % or greater, and also, for example, 3 mass % or less or 2 mass % or less. Furthermore, the content percentage of the rare earth ions relative to the amount of fluoride particles in the liquid medium is, for example, 0.2 mass % or greater or 0.5 mass % or greater, and also, for example, 30 mass % or less or 20 mass % or less. When the concentration of the rare earth ions is greater than or equal to the lower limit described above, the adherence ratio of the rare earth phosphate to the fluoride particles tends to be further improved. When the concentration of the rare earth ions is less than or equal to the upper limit described above, the rare earth phosphate tends to be easily adhered more uniformly to the surfaces of the fluoride particles.

The contact temperature between the rare earth ions and the phosphate ions forming the rare earth phosphate is, for example, in a range from 10° C. to 50° C., and preferably from 20° C. to 35° C. In addition, the contact time is, for example, in a range from 1 minute to 1 hour, and preferably from 3 minutes to 30 minutes. The contact may be caused while stirring the liquid medium.

After the adherence step, a separation step may be provided in which the fluoride particles to which the rare earth phosphate is adhered is separated from the liquid medium. The separation can be caused by, for example, a solid-liquid separation means such as filtration or centrifugal separation. As necessary, the phosphor yielded by solid-liquid separation may also be subjected to a washing treatment, a drying treatment, or the like.

The method for manufacturing a fluoride phosphor may further include, after the synthesizing step, additional steps such as a step of recovering, through solid-liquid separation, the fluoride phosphor obtained in the synthesizing step, and a step of drying the solid-liquid separated fluoride phosphor.

The method for manufacturing a fluoride phosphor may include a surface treatment step in which the fluoride phosphor obtained in the synthesizing step is treated with a coupling agent. The manufacturing method may further include carrying out a silane coupling treatment after the fluoride particles have been covered with the oxide derived from the metal alkoxide. In the surface treatment step, the fluoride phosphor and a coupling agent are brought into contact, and thereby a surface treatment layer including a functional group derived from the coupling agent can be provided on the surface of the fluoride phosphor. Through this, for example, moisture resistance of the fluoride phosphor is improved.

Specific examples of the coupling agent used in the surface treatment step are as described above. The amount of the coupling agent used in the surface treatment step may be, for example, in a range from 0.5 mass % to 10 mass %, and preferably in a range from 1 mass % to 5 mass %, relative to the content of the fluoride phosphor. The contact temperature between the fluoride phosphor and the coupling agent may be, for example, in a range from 0° C. to 70° C., and preferably from 10° C. to 40° C. Furthermore, the contact time between the fluoride phosphor and the coupling agent may be, for example, in a range from 1 minute to 10 hours, and preferably from 10 minutes to 1 hour.

### Light-Emitting Device

The light-emitting device includes: a fluorescent member containing a resin and a first phosphor containing the fluoride phosphor; and a light-emitting element having a light emission peak wavelength in a wavelength range from 380 nm to 485 nm. The light-emitting device may further include other constituent members as necessary.

An example of the light-emitting device will be described based on the drawings. FIG. 1 is a schematic cross-sectional view illustrating one example of a light-emitting device according to the present embodiment. This light-emitting device is an example of a surface-mounted light-emitting device. The light-emitting device 100 includes a light-emitting element 10 that emits light having a peak emission wavelength on the short-wavelength side of visible light (for example, in a range from 380 nm to 485 nm), and a molded body 40 on which the light-emitting element 10 is mounted. The molded body 40 has a first lead 20 and a second lead 30, and is integrally molded using a thermoplastic resin or a thermosetting resin. A recessed portion having a bottom surface and side surfaces is formed in the molded body 40, and the light-emitting element 10 is placed on the bottom surface of the recessed portion. The light-emitting element 10 includes a pair of positive and negative electrodes, and the pair of the positive and negative electrodes are electrically connected to the first lead 20 and the second lead 30 via wires 60. The light emitting element 10 is sealed with a fluorescent member 50. The fluorescent member 50 contains a phosphor 70 including a fluoride phosphor that converts the wavelength of light from the light-emitting element 10. The phosphor 70 may contain the first phosphor including the fluoride phosphor, and a second phosphor which, in response to excitation light from the light-emitting element 10, emits light having an emission peak wavelength in a wavelength range different from that of the fluoride phosphor.

The fluorescent member may contain a resin and a phosphor. Examples of the resin constituting the fluorescent member include a silicone resin, an epoxy resin, a modified silicone resin, a modified epoxy resin, and an acrylic resin. For example, the refractive index of a silicone resin may be in a range from 1.35 to 1.55, and is more preferably in a range from 1.38 to 1.43. When the refractive index of the silicone resin is within these ranges, the silicone resin has excellent transmissivity and can be suitably used as a resin constituting the fluorescent member. Here, the refractive index of the silicone resin is the refractive index after curing, and is measured in accordance with JIS K 7142:2008. The fluorescent member may further include a light-diffusing material in addition to the resin and the phosphor. When a light-diffusing material is included, directivity from the light-emitting element can be alleviated, and a viewing angle can be increased. Examples of the light-diffusing material include silicon oxide, titanium oxide, zinc oxide, zirconium oxide, and aluminum oxide.

The light-emitting element emits light having an emission peak wavelength in a wavelength range from 380 nm to 485 nm, which is a short wavelength range of visible light. The light-emitting element may be an excitation light source that excites a fluoride phosphor. The light-emitting element preferably has an emission peak wavelength within a range from 380 nm to 480 nm, more preferably has an emission peak wavelength within a range from 410 nm to 480 nm, and even more preferably has an emission peak wavelength within a range from 430 nm to 480 nm. A semiconductor light-emitting element is preferably used as the light-emitting element of the excitation light source. A semiconductor light-emitting element used as an excitation light source enables a stable light-emitting device that exhibits high efficiency and high output linearity with respect to an input and that is strong against mechanical impact. As the semiconductor light-emitting element, for example, a semiconductor light-emitting element that uses a nitride-based semiconductor can be used. The full width at half maximum of the emission peak in the emission spectrum of the light-emitting element is preferably 30 nm or less, for example.

The light-emitting device includes a first phosphor including a fluoride phosphor. Details of the fluoride phosphor constituting the light-emitting device are described above. The fluoride phosphor is contained, for example, in a fluorescent member covering the excitation light source. In the light-emitting device in which the excitation light source is covered with the fluorescent member containing the fluoride phosphor, some of the light emitted from the excitation light source is absorbed by the fluoride phosphor and emitted as red light. When an excitation light source that emits light having an emission peak wavelength in the range from 380 nm to 485 nm is used, the emitted light can be utilized more effectively, loss of light emitted from the light-emitting device can be reduced, and a highly efficient light-emitting device can be provided.

The light-emitting device preferably further includes, in addition to the first phosphor containing the fluoride phosphor, a second phosphor containing a phosphor other than the fluoride phosphor. The phosphor other than the fluoride phosphor may be any phosphor that absorbs light from the light source and wavelength converts the light into light having a wavelength different from that of the fluoride phosphor. Similar to the first phosphor, the second phosphor can be contained in the fluorescent member.

The second phosphor may have an emission peak wavelength in a range from 495 nm to 590 nm, and may preferably include at least one material selected from the group consisting of β-sialon phosphors, halosilicate phosphors, silicate phosphors, rare earth-aluminate phosphors, perovskite light-emitting materials, and nitride phosphors. The β-sialon phosphor may have a composition represented by Formula (IIa), for example. The halosilicate phosphor may have a composition represented by Formula (IIb), for example. The silicate phosphor may have a composition represented by Formula (IIc), for example. The rare earth-aluminate phosphor may have a composition represented by Formula (IId). The perovskite light-emitting material may have a composition represented by Formula (IIe), for example. The nitride phosphor may have a composition represented by Formula (IIf), (IIg), or (IIh), for example. When the fluorescent member contains a β-sialon phosphor or a perovskite-based light-emitting material as the second phosphor other than the fluoride phosphor, a light-emitting device can be obtained with a wider range of color reproducibility when the light-emitting device is used as, for example, a light source for backlight. When the fluorescent member contains, as the second phosphor other than the fluoride phosphor, a halosilicate phosphor, a silicate phosphor, a rare earth-aluminate phosphor, or a nitride phosphor, a light-emitting device can be obtained with higher color rendering properties or higher luminous efficiency when the light-emitting device is used as, for example, an illumination light source.

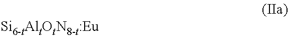

where in Formula (IIa), t satisfies 0<t≤4.2.

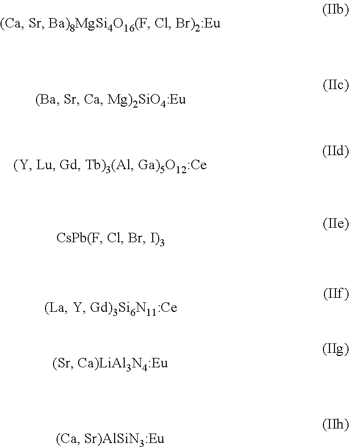

In the present specification, a plurality of elements separated by commas (,) in a formula representing the composition of the phosphor or light-emitting material means that at least one element among the plurality of elements is contained in the composition. In a formula representing the composition of the phosphor, characters preceding the colon (:) represent a host crystal, and characters following the colon (:) represent an activating element.

The average particle size of the second phosphor is, for example, in a range from 0.1 μm to 7 μm, and is preferably 0.2 μm or greater, or 0.5 μm or greater. Furthermore, the average particle size is preferably 5 μm or smaller, or 3 μm or smaller. The average particle size of the second phosphor is measured by the Fischer sub sieve sizer (FSSS) method. The fluorescent member may include one type of the second phosphor alone, or may include two or more types in combination.

The fluorescent member may further contain at least one type of quantum dots in addition to the first phosphor. The quantum dots may be quantum dots that absorb light from the light source and convert the light to light of a wavelength differing from that of the first phosphor, or may be quantum dots that convert the absorbed light to light of approximately the same wavelength. Examples of quantum dots include quantum dots having a perovskite structure with a composition such as (Cs, FA, MA)(Pb, Sn)(Cl, Br, I)₃ (where FA denotes formamidinium and MA denotes methylammonium), quantum dots having a chalcopyrite structure with a composition such as (Ag, Cu, Au)(In, Ga)(S, Se, Te)₂, semiconductor quantum dots such as (Cd, Zn)(Se, S), and InP-based semiconductor quantum dots. The quantum dots may include at least one type selected from the group consisting of these. Here, a plurality of elements or cations separated by commas (,) in a formula representing the composition of the quantum dots means that at least one element among the plurality of elements or cations is contained in the composition.

The present disclosure further encompasses the following aspects. Use of the fluoride phosphor in the manufacturing of the light-emitting device. The fluoride phosphor used for manufacturing the light-emitting device. Use of the fluoride particles in the manufacturing of the fluoride phosphor. The fluoride particles used for manufacturing the fluoride phosphor.

### EXAMPLES

The present invention will be described in detail below through examples, but the present invention is not limited to these examples.

### Manufacturing Example 1

Through the method described above, fluoride particles A1 were obtained as a phosphor having a first theoretical composition (hereinafter, may be abbreviated as “KSF”) represented by K₂SiF₆:Mn with a Mn content percentage of 1.5 mass %.

### Manufacturing Example 2

Through the method described above, fluoride particles A2 were obtained as a phosphor having a second theoretical composition (hereinafter, may be abbreviated as “KSAF”) represented by K₂Si_{0.99}Al_{0.01}F_{5.99}:Mn with a Mn content percentage of 1.5 mass %.

### Manufacturing Example 3

Amounts of 15.0 g of 35 mass % hydrogen peroxide and 735.0 g of pure water were added to 150.0 g of an aqueous sodium salt solution of phosphoric acid (phosphoric acid concentration: 2.4 mass %), and while the mixture was stirred (with stirring blades at a rotational speed of 400 rpm) at room temperature, 300 g of the fluoride particles A1 produced in Manufacturing Example 1 were added thereto, and a phosphor slurry was thereby prepared.

Subsequently, 23.4 g of lanthanum nitrate dihydrate was dissolved in 156.6 g of pure water to form a lanthanum nitrate aqueous solution (lanthanum concentration: 5.0 mass %), and the lanthanum nitrate aqueous solution was then added dropwise over approximately 1 minute to the phosphor slurry. Stirring was stopped approximately 30 minutes after the dropwise addition was completed, and the mixture was allowed to stand. Subsequently, the supernatant was removed, after which the precipitate was sufficiently washed with washing water containing 1 mass % of hydrogen peroxide. The obtained precipitate was subjected to solid-liquid separation, and then washed with ethanol and dried at 90° C. for 10 hours, and thereby fluoride particles A3 having lanthanum phosphate disposed on the surface were prepared as Manufacturing Example 3.

### Manufacturing Example 4

Fluoride particles A4 of Manufacturing Example 4 in which lanthanum phosphate was disposed on the surface were produced by the same method as in Manufacturing Example 3 with the exception that the fluoride particles A2 produced in Manufacturing Example 2 were used.

### Manufacturing Example 5

Through the method described above, fluoride particles A5 were obtained as a phosphor having a second theoretical composition represented by K₂Si_{0.99}Al_{0.01}F_{5.99}:Mn with a Mn content percentage of 1.0 mass %.

### Manufacturing Example 6

Fluoride particles A6 of Manufacturing Example 6 in which lanthanum phosphate was disposed on the surface were produced by the same method as in Manufacturing Example 3 with the exception that the fluoride particles A5 produced in Manufacturing Example 5 were used.

### Manufacturing Example 7

Through the method described above, a phosphor having a second theoretical composition represented by K₂Si_{0.99}Al_{0.01}F_{5.99}:Mn with a Mn content percentage of 1.2 mass % was obtained, after which fluoride particles A7 of Manufacturing Example 7 in which lanthanum phosphate was disposed on the surface were produced by the same method as in Manufacturing Example 3.

### Example 1

The fluoride particles manufactured in Manufacturing Example 1 were weighed to obtain an amount of 300 g and then added to a mixed solution of 540 μmL of ethanol, 130.2 μmL of ammonia water containing 16.5 mass % of ammonia, and 60 μmL of pure water, and the liquid temperature was maintained at normal temperature while the solution was stirred with stirring blades at 400 rpm, and a reaction mother liquid was thereby produced. Tetraethoxysilane (TEOS: Si(OC₂H₅)₄) was weighed to obtain an amount of 32.1 g, and was then added dropwise over a period of approximately 3 hours to the reaction mother liquid under stirring. Subsequently, stirring was continued for 1 hour, and 10 g of 35 mass % hydrogen peroxide (H₂O₂) was further added, after which the stirring was stopped. The obtained precipitate was subjected to solid-liquid separation, and then washed with ethanol and dried at 105° C. for 10 hours, and thereby a fluoride phosphor E1 covered with silicon dioxide (SiO₂) was prepared as Example 1. The amount of tetraethoxysilane added dropwise was approximately 3 mass % in terms of the silicon dioxide relative to the fluoride particles.

### Example 2

A fluoride phosphor E2 of Example 2 was produced by the same method as in Example 1 with the exception that the dropwise addition amount of tetraethoxysilane was 107.1 g. The amount of tetraethoxysilane added dropwise was approximately 10 mass % in terms of the silicon dioxide relative to the fluoride particles.

A backscattered electron image obtained by observing, with a scanning electron microscope, a fluoride phosphor obtained in Example 2 is presented in FIG. 2. The relatively large number of gray portions observed in FIG. 2 correspond to a film of silicon dioxide, and the relatively dark gray portions observed in a net-like pattern between the gray portions correspond to exposed portions of the surfaces of the fluoride particles. As illustrated in FIG. 2, in the fluoride phosphor, most of the surface of the fluoride particle is covered with silicon dioxide. It is clear that the silicon dioxide covering the fluoride particles is in the form of a continuous film and not in the form of particles. It is thought that direct contact between the fluoride particles and the resin is effectively suppressed by the silicon dioxide covering the fluoride particles in the form of a film. In addition, cracks (slightly dark gray portions) are present in some of the silicon dioxide film. It is thought that direct contact between the fluoride particles and the resin can be more effectively suppressed as these cracks become smaller.

### Example 3

A fluoride phosphor E3 of Example 3 was produced by the same method as in Example 1 with the exception that the dropwise addition amount of tetraethoxysilane was 214.2 g. The amount of tetraethoxysilane added dropwise was approximately 20 mass % in terms of the silicon dioxide relative to the fluoride particles.

### Example 4

A fluoride phosphor E4 of Example 4 was produced by the same method as in Example 1 with the exception that the fluoride particles A2 produced in Manufacturing Example 2 were used, stirring was implemented at 500 rpm, and the dropwise addition amount of tetraethoxysilane was 107.1 g.

### Example 5

A fluoride phosphor E5 of Example 5 was produced by the same method as in Example 1 with the exception that the fluoride particles A3 produced in Manufacturing Example 3 were weighed to obtain an amount of 100 g, the amount of ethanol was changed to 180 μmL, the amount of ammonia water containing 16.5 mass % of ammonia was changed to 43.4 μmL, the amount of pure water was changed to 20 μmL, stirring with stirring blades was implemented at 300 rpm, the amount of tetraethoxy silane was changed to 35.7 g, and the dropwise addition occurred over a period of 6 hours.

### Example 6

The fluoride particles A3 produced in Manufacturing Example 3 were weighed to obtain an amount of 100 g, which was then added to a mixed solution obtained by mixing 139 μmL of ethanol and 35.7 mL of pure water, the liquid temperature of the resulting solution was maintained at normal temperature while the solution was stirred with stirring blades at 300 rpm, and a reaction mother liquid was thereby obtained. Tetraethoxysilane was weighed to obtain an amount of 35.7 g, which was then used as a liquid A, and ammonia water containing 16.5 mass % of ammonia was weighed to obtain an amount of 42.9 g, which was then used as a liquid B. The liquid A and the liquid B were added dropwise over a period of approximately 3 hours to the reaction mother liquid while stirring, after which stirring was continued for 1 hour, and 10 g of 35 mass % hydrogen peroxide (H₂O₂) was further added, after which the stirring was stopped. The resultant precipitate was subjected to solid-liquid separation, and then washed with ethanol and dried at 105° C. for 10 hours, and thereby a fluoride phosphor E6 of Example 6 was produced.

### Example 7

First, 50 g of the fluoride phosphor E6 produced in Example 6 was weighed. Subsequently, 84.9 μmL of ethanol, 5.8 μmL of pure water, and decyltrimethoxysilane ((CH₃O)₃Si(CH₂)₉CH₃) as a silane coupling agent were mixed and stirred for 30 minutes, after which the solution was allowed to stand for 20 hours or longer. The fluoride phosphor E6 prepared in Example 6 was added to the solution, and the mixture was stirred at 200 rpm for 1 hour, after which the stirring was stopped. The resultant precipitate was subjected to solid-liquid separation and then dried at 105° C. for 10 hours to carry out a silane coupling treatment, and thereby a fluoride phosphor E7 was produced.

### Example 8

A fluoride phosphor E8 of Example 8 was produced by the same method as in Example 4 with the exception that the fluoride particles A4 produced in Manufacturing Example 4 were used.

### Example 9

A fluoride phosphor E9 of Example 9 was produced by the same method as in Example 7 with the exception that the fluoride phosphor E8 produced in Example 8 was used.

### Example 10

A fluoride phosphor E10 of Example 10 was produced by the same method as in Example 2 with the exception that the fluoride particles A5 produced in Manufacturing Example 5 were used, the stirring speed was changed to 350 rpm, and the dropwise addition time of the tetraethoxysilane was changed to 6 hours.

### Example 11

A fluoride phosphor E11 of Example 11 was produced by the same method as in Example 10 with the exception that the fluoride particles A6 produced in Manufacturing Example 6 were used.

### Example 12

A fluoride phosphor E12 of Example 12 was produced by the same method as in Example 7 with the exception that the fluoride phosphor E11 produced in Example 11 was used.

### Example 13

A fluoride phosphor E13 of Example 13 was produced by the same method as in Example 10 with the exception that the dropwise addition amount of tetraethoxysilane was changed to 64.3 g.

### Example 14

A fluoride phosphor E14 of Example 14 was produced by the same method as in Example 10 with the exception that the dropwise addition amount of tetraethoxysilane was changed to 32.2 g.

### Example 15

A fluoride phosphor was obtained by the same method as in Example 13 with the exception that the fluoride particles A7 produced in Manufacturing Example 7 were used. The obtained phosphor was subjected to a silane coupling treatment by the same method as in Example 7 with the exception that hexyltrimethoxysilane was used as the silane coupling agent, and thereby a fluoride phosphor E15 of Example 15 was produced.

### Example 16

A fluoride phosphor E16 of Example 16 was produced by the same method as in Example 15 with the exception that vinyltrimethoxysilane was used as the silane coupling agent.

### Example 17

A fluoride phosphor E17 of Example 17 was produced by the same method as in Example 15 with the exception that 3-aminopropyl triethoxysilane was used as the silane coupling agent.

### Example 18

A fluoride phosphor E18 of Example 18 was produced by the same method as in Example 15 with the exception that 3-glycidoxypropyl trimethoxysilane was used as the silane coupling agent.

### Reference Example 1

The fluoride particles A1 obtained in Manufacturing Example 1 were used as a fluoride phosphor C1 of Reference Example 1.

### Reference Example 2

The fluoride particles A2 obtained in Manufacturing Example 2 were used as a fluoride phosphor C2 of Reference Example 2.

### Reference Example 3

The fluoride particles A3 obtained in Manufacturing Example 3 were used as a fluoride phosphor C3 of Reference Example 3.

### Reference Example 4

The fluoride particles A4 obtained in Manufacturing Example 4 were used as a fluoride phosphor C4 of Reference Example 4.

### Reference Example 5

The fluoride particles A6 obtained in Manufacturing Example 6 were used as a fluoride phosphor C5 of Reference Example 5.

### Reference Example 6

The fluoride particles A7 obtained in Manufacturing Example 7 were used as a fluoride phosphor C6 of Reference Example 6.

### Evaluation

### (1) Amount of Silicon Dioxide

The composition of each of the obtained fluoride phosphors was analyzed by ICP emission spectrometry, the amount of silicon dioxide covering the fluoride particles was calculated from the difference in the analyzed Si concentration of the fluoride phosphor covered with silicon dioxide and obtained in the respective Example and the analyzed Si concentration of the fluoride phosphor of the respective Reference Example, and thereby the content percentage (SiO₂ analysis value) of silicon dioxide in relation to the fluoride phosphor was determined. The results are indicated in Tables 1 to 4.

### (2) X-ray Fluorescence Elemental Analysis: XRF Evaluation

The peak intensity of Kα rays of the F element of each of the obtained fluoride phosphors was measured by X-ray fluorescence spectrometry (XRF) using an XRF device (product name: ZSX Primus II, available from Rigaku Corporation). The peak intensity ratios of the fluoride phosphors of Examples 1 to 3 were calculated as relative values with the peak intensity of the fluoride phosphor of Reference Example 1 being 100. The peak intensity ratio of the fluoride phosphor of Example 4 was similarly calculated as a relative value with the peak intensity of the fluoride particles of Reference Example 2 being 100. From the calculated peak intensity ratios, the average thickness of the silicon dioxide film on the fluoride phosphor of each Example was calculated using a database from The Center for X-Ray Optics (CXRO). The results are indicated in Table 1.

### (3) Scanning Electron Microscope Observation

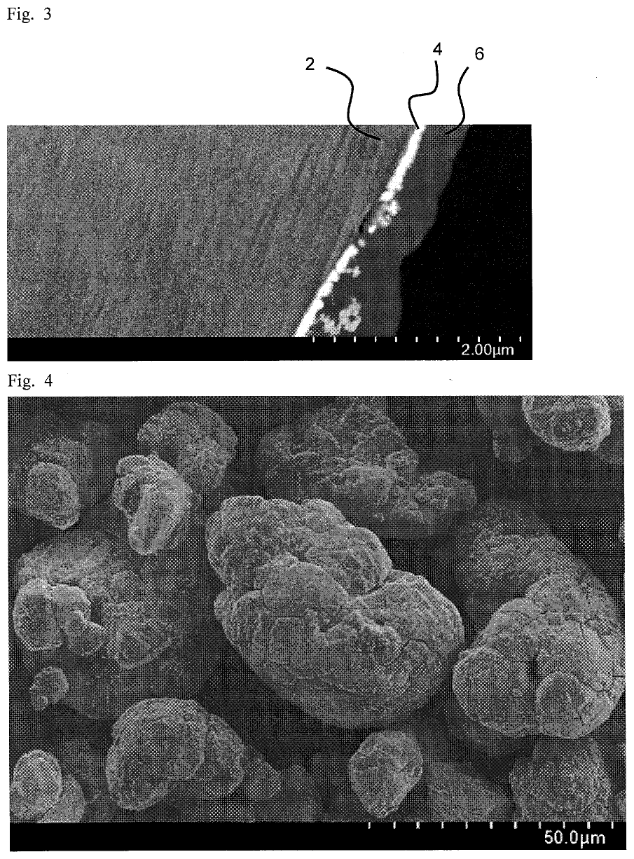

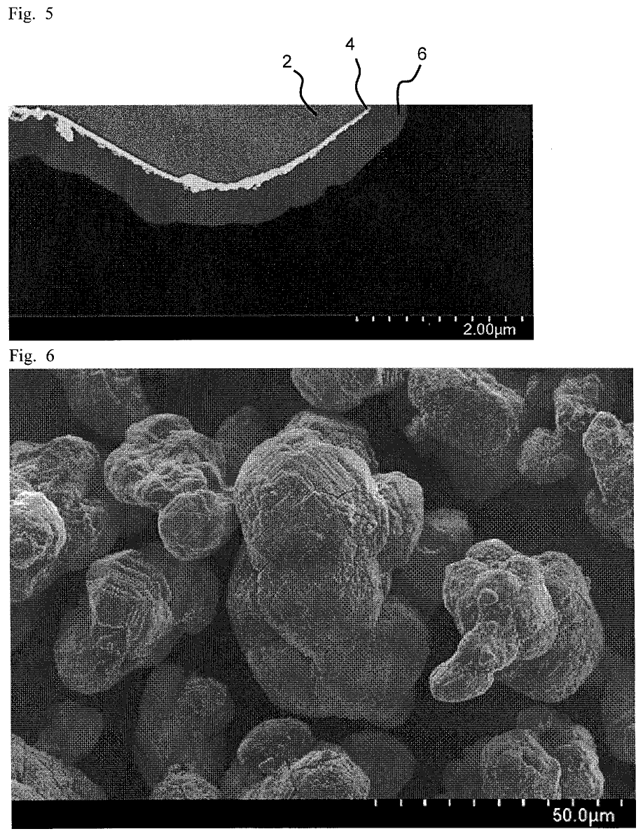

The fluoride phosphors obtained in Examples 6 and 8 were subjected to image observation using a scanning electron microscope (SEM). The SEM images are presented in FIGS. 4 and 6. Furthermore, arbitrary cross sections of the fluoride phosphors of Examples 6 and 8 were observed using a scanning electron microscope (SEM), and the average thickness of the silicon dioxide film of each was measured by image analysis. Specifically, a plurality of fluoride phosphor particles were embedded in a resin, and a cross-sectional sample was prepared by ion milling such that the cross-section of the fluoride phosphor particles could be observed with a scanning electron microscope. The cross-sectional SEM images are indicated in FIGS. 3 and 5.

The thickness of the silicon dioxide film was measured at five locations for each fluoride phosphor particle in the obtained cross-sectional SEM image, and the actually measured average thickness was calculated as an arithmetic average of the thicknesses at a total of 25 locations from five particles. Here, the thickness of the silicon dioxide film was defined as the thickness of the film visible on the SEM image including a portion where the film was cut obliquely in relation to the thickness direction. The results are indicated in Table 2.

### (4) Total Carbon (TC)

The total carbon (TC) of each of the obtained fluoride phosphors of Examples 7, 9, 12, and 15 to 18 and Reference Examples 3 and 4 was analyzed using a total organic carbon meter (product name: TOC-L, available from Shimadzu Corporation). The results are indicated in Tables 2, 4 and 5.

### (5) Lanthanum Content Percentage

The lanthanum content percentage of each of the obtained fluoride phosphors of Examples 5 to 9 and 11 to 18 and Reference Examples 3 to 6 was analyzed by inductively coupled plasma atomic emission spectrometry (ICP-AES) to determine the content percentage (La analysis value) with respect to the fluoride particles. The results are indicated in Tables 2 and 4.

### (6) Manganese Content

The manganese content percentage of each of the obtained fluoride phosphors of Examples 10 to 18 and Reference Examples 1, 3, 5 and 6 was analyzed by inductively coupled plasma atomic emission spectrometry (ICP-AES) to determine the content percentage (Mn analysis value) with respect to the fluoride phosphor. The results are indicated in Tables 3 and 4.

### (7) Evaluation of Mass Change of Resin Composition

The influence of the fluoride phosphor on the change in mass of a resin composition containing a resin and the fluoride phosphor was evaluated as follows. A resin composition was prepared by mixing, into a silicone resin, 33 mass % of the fluoride phosphor in relation to the silicone resin. Approximately 1 g of the resultant resin composition was weighed on an aluminum foil and cured, after which the difference between the mass of the cured resin composition and the mass of the aluminum foil was calculated as an initial value. The resin composition cured on the aluminum foil was left to stand in a small oven (product name: LH-114 Constant Climate Cabinet, available from Espec Corp.) maintained at 200° C., and the mass after 100 hours, after 300 hours, after 500 hours, and after 1000 hours was measured. The mass retention rate (%) of the resin composition after the passage of each time was calculated with the initial mass value being 100%. A higher mass retention rate indicates a greater suppression of a reaction between the fluoride phosphor and the resin, meaning that the durability of the resin composition is excellent. A silicone resin selected from commercially available silicone resins was used for the evaluation. Specifically, Examples 1 to 9 and Reference Examples 1 to 4 were evaluated using a dimethyl silicone resin (product name: KER-2936; refractive index of 1.41, hereinafter referred to as “dimethyl silicone resin 1”) available from Shin-Etsu Chemical Co., Ltd. In Examples 10 and 11 and Reference Example 1, evaluations were also conducted using a dimethyl silicone resin (trade name: OE-6351; refractive index: 1.41, hereinafter, referred to as “dimethyl silicone resin 2”) available from Dow Corning Toray Co., Ltd., a phenyl silicone resin (trade name OE-6630; refractive index 1.53, hereinafter, referred to as “phenyl silicone resin 1”) available from Dow Corning Toray Co., Ltd., and a phenyl silicone resin (refractive index 1.50, hereinafter referred to as “phenyl silicone resin 2”) having a refractive index differing from that of the phenyl silicone resin 1.

### (8) Durability Evaluation

The durability of each fluoride phosphor obtained above was evaluated as follows. The internal quantum efficiency of each fluoride phosphor with respect to excitation light of 450 nm was measured using a quantum efficiency-measuring apparatus (product name: QE-2000, available from Otsuka Electronics Co., Ltd.), and the measured internal quantum efficiency was used as the initial characteristic. Subsequently, the fluoride particles or the fluoride phosphor was placed in a glass petri dish and allowed to stand for 100 hours in a small high-temperature, high-humidity tank (available from Espec Corp.) maintained at a temperature of 85° C. and a relative humidity of 85%. Subsequently, the internal quantum efficiency of each fluoride phosphor was measured by the same method, and the quantum efficiency maintenance rate (%) based on the initial characteristic being 100% was calculated. A higher quantum efficiency maintenance rate means better durability. The results are indicated in Tables 1 to 5.

### Manufacturing Example 1 of Light-Emitting Device

The fluoride phosphors of Examples 1 to 9 and Reference Examples 1 to 4 were respectively used as a first phosphor. A β-sialon phosphor having a composition represented by Si_{5.81}Al_{0.19}O_{0.19}N_{7.81}:Eu and having an emission peak near 540 nm was used as a second phosphor. A resin composition was obtained by mixing a silicone resin with a phosphor 70 produced by blending the first phosphor 71 and the second phosphor 72 such that as the chromaticity coordinates in the CIE1931 color system, x was around 0.280 and y was around 0.270. Subsequently, a molded body 40 having a recessed portion was prepared, a light-emitting device 10 μmade of a gallium nitride-based compound semiconductor and having an emission peak wavelength of 451 nm was disposed on the first lead 20 at the bottom of the recessed portion, and then electrodes of the light-emitting device 10 were connected to the first lead 20 and the second lead 30 by respective wires 60. Further, using a syringe, the resin composition was injected into the recessed portion of the molded body 40 so as to cover the light-emitting element 10, and the resin composition was cured to form a fluorescent member, and thereby respective light-emitting devices 1 were manufactured.

### Manufacturing Example 2 of Light-Emitting Device

The fluoride phosphors of Examples 10 to 18 and Reference Examples 3, 5, and 6 were respectively used as the first phosphor. A rare-earth aluminate phosphor having a composition represented by Lu₃Al₅O₁₁:Ce and having an emission peak near 530 nm, a rare-earth aluminate phosphor having a composition represented by Y₃Al₅O₁₁:Ce and having an emission peak near 535 nm, and a nitride phosphor having a composition represented by (Ca, Sr)AlSiN₃:Eu and having an emission peak near 630 nm were used in combination as the second phosphor. Respective light-emitting devices 2 were manufactured in the same manner as in Manufacturing Example 1 of the light-emitting device, with the exception that a resin composition was obtained by mixing silicone resin with the phosphor 70 produced by blending the first phosphor 71 and the second phosphor 72 such that as the chromaticity coordinates in the CIE1931 color system, x was around 0.459 and y was around 0.411.

### Durability Evaluation 1

The light-emitting devices 1 or 2 μmanufactured using the respective fluoride phosphors obtained in Examples 1 to 9 and 15 to 18 and Reference Examples 1 to 4 and 6 were each subjected to a durability test 1 by being stored in an environmental tester at a temperature of 85° C. and 85% RH for 500 hours. A luminous flux maintenance rate 1 (%) of each light-emitting device 1 or 2 after the durability test 1 was determined based on the luminous flux of the light-emitting device 1 or 2 before the durability test 1 being 100%. A higher luminous flux maintenance rate 1 indicates more excellent durability against high temperature and high humidity conditions. The results are indicated in Tables 1, 2, and 5.

### Durability Evaluation 2

The light-emitting devices 2 μmanufactured using each of the fluoride phosphors obtained in Examples 10 to 18 and Reference Examples 3, 5, and 6 were each subjected to a durability test 2 by being driven at a current value of 150 μmA for 1000 hours in a non-humidified environmental tester at a temperature of 85° C. A luminous flux maintenance rate 2 (%) of the light-emitting device 2 after the durability test 2 was determined based on the luminous flux of the light-emitting device 2 before the durability test 2 being 100%. A higher luminous flux maintenance rate 2 indicates more excellent durability against high heat. The results are indicated in Tables 4 and 5.

TABLE 1

| | | | | | | | | | | | Light- |
|---|---|---|---|---|---|---|---|---|---|---|---|
| | | | | | | | | | | | emitting |
| | Phosphor | | | | | | | | | | device 1 |
| | | SiO₂ | SiO₂ | | | Quantum | | | | | Luminous |
| | Phosphor | charged | analysis | Peak | Average | efficiency | | | | | flux |
| | compo- | amount | value | intensity | thickness | maintenance | Mass retention rate (%) | | | | maintenance |
| | sition | (mass %)) | (mass %) | ratio | (μm) | rate (%) | 100 h | 300 h | 500 h | 1000 h | rate 1 (%) |
| Reference | KSF | 0 | — | 100 | 0 | 79.2 | 92 | 36 | 32 | 31 | 85 |
| Example 1 | | | | | | | | | | | |
| Example 1 | | 3 | 3.3 | 77 | 0.13 | 90.9 | 100 | 96 | 90 | 68 | 86 |
| Example 2 | | 10 | 9.2 | 44 | 0.44 | 95.3 | 100 | 97 | 95 | 92 | 90 |
| Example 3 | | 20 | 14.5 | 32 | 0.54 | 91.8 | 100 | 97 | 95 | 93 | 91 |
| Reference | KSAF | 0 | — | 100 | 0 | 68.9 | 79 | 37 | 34 | 31 | 88 |
| Example 2 | | | | | | | | | | | |
| Example 4 | | 10 | 9.1 | 42 | 0.45 | 84.9 | 100 | 97 | 95 | 91 | 91 |

TABLE 2

| | | | | | | | | | | | | Light- |
|---|---|---|---|---|---|---|---|---|---|---|---|---|
| | | | | | | | | | | | | emitting |
| | Phosphor | | | | | | | | | | | device 1 |
| | | SiO₂ | SiO₂ | La | TC | Measured | Quantum | | | | | Luminous |
| | Phosphor | charged | analysis | analysis | analysis | average | efficiency | | | | | flux |
| | compo- | amount | value | value | value | thickness | maintenance | Mass retention rate (%) | | | | maintenance |
| | sition | (mass %) | (mass %) | (mass %) | (ppm) | (μm) | rate (%) | 100 h | 300 h | 500 h | 1000 h | rate 1 (%) |
| Reference | KSF | 0 | — | 1.36 | 50 | — | 91.7 | 99 | 69 | 49 | 41 | 87 |
| Example 3 | | | | | | | | | | | | |
| Example 5 | | 10 | 8.0 | 1.08 | — | — | 95.1 | 100 | 98 | 96 | 92 | 92 |
| Example 6 | | 10 | 8.9 | 1.08 | — | 0.50 | 93.2 | 100 | 97 | 96 | 92 | 89 |
| Example 7 | | 10 | 9.0 | 1.06 | 280 | — | 98.4 | 100 | 97 | 96 | 92 | 95 |
| Reference | KSAF | 0 | — | 1.02 | 20 | — | 90.3 | 99 | 64 | 45 | 38 | 87 |
| Example 4 | | | | | | | | | | | | |
| Example 8 | | 10 | 9.1 | 0.93 | — | 0.44 | 92.6 | 100 | 97 | 95 | 92 | 91 |
| Example 9 | | 10 | 8.7 | 0.91 | 170 | — | 93.7 | 99 | 97 | — | — | 91 |

TABLE 3

| | | SiO₂ | SiO₂ | Mn | La | Quantum | | | | |
|---|---|---|---|---|---|---|---|---|---|---|
| | Phosphor | charged | analysis | analysis | analysis | efficiency | | | | |
| | compo- | amount | value | value | value | maintenance | | Mass retention rate (%) | | |
| | sition | (mass %) | (mass %) | (mass %) | (mass %) | rate (%) | Resin | 100 h | 300 h | 500 h |
| Reference | KSF | 0 | — | 1.50 | 0 | 79.2 | Dimethyl silicone resin 1 | 92 | 36 | 32 |
| Example 1 | | | | | | | Dimethyl silicone resin 2 | 41 | 38 | 37 |
| | | | | | | | Phenyl silicone resin 1 | 88 | 79 | 76 |
| | | | | | | | Phenyl silicone resin 2 | 92 | 88 | 86 |
| Example 10 | KSAF | 10 | 9.0 | 0.92 | 0 | 93.5 | Dimethyl silicone resin 1 | 100 | 96 | 95 |
| | | | | | | | Dimethyl silicone resin 2 | 97 | 86 | 74 |
| | | | | | | | Phenyl silicone resin 1 | 98 | 95 | 93 |
| | | | | | | | Phenyl silicone resin 2 | 100 | 96 | 94 |
| Example 11 | | | 8.6 | 0.91 | 1.03 | 95.9 | Dimethyl silicone resin 1 | 100 | 97 | 96 |
| | | | | | | | Dimethyl silicone resin 2 | 98 | 92 | 85 |
| | | | | | | | Phenyl silicone resin 1 | 98 | 96 | 95 |
| | | | | | | | Phenyl silicone resin 2 | 97 | 96 | 95 |

TABLE 4

| | | | | | | | | | | | | Light- |
|---|---|---|---|---|---|---|---|---|---|---|---|---|
| | | | | | | | | | | | | emitting |
| | Phosphor | | | | | | | | | | | device 2 |
| | | SiO₂ | SiO₂ | Mn | La | TC | Quantum | | | | | Luminous |
| | Phosphor | charged | analysis | analysis | analysis | analysis | efficiency | | | | | flux |
| | compo- | amount | value | value | value | value | maintenance | | Mass retention rate (%) | | | maintenance |
| | sition | (mass %) | (mass %) | (mass %) | (mass %) | (ppm) | rate (%) | Resin | 100 h | 300 h | 1000 h | rate 2 (%) |
| Reference | KSF | 0 | — | 1.50 | 1.36 | 50 | 91.7 | Dimethyl | 99 | 69 | 41 | 97.5 |
| Example 3 | | | | | | | | silicone | | | | |
| Reference | KSAF | — | — | 1.00 | 1.14 | — | 93.9 | resin 1 | 98 | 78 | 45 | 96.3 |
| Example 5 | | | | | | | | | | | | |
| Example 10 | | 10 | 9.0 | 0.92 | — | — | 93.5 | | 100 | 96 | 92 | 96.4 |
| Example 11 | | 10 | 8.6 | 0.91 | 1.03 | — | 95.9 | | 100 | 97 | 93 | 97.7 |
| Example 12 | | 10 | 8.7 | 0.92 | 1.02 | 260 | 98.2 | | 100 | 97 | 92 | 98.4 |
| Example 13 | | 6 | 5.9 | 0.94 | — | — | 94.9 | | 100 | 97 | 90 | 99.0 |
| Example 14 | | 3 | 3.0 | 0.95 | — | — | 96.8 | | 100 | 97 | 80 | 98.7 |

TABLE 5

| | Phosphor | | | | | | | | | Light-emitting device 2 | |
|---|---|---|---|---|---|---|---|---|---|---|---|
| | | SiO₂ | SiO₂ | Mn | La | TC | Quantum | | Mass | Luminous | Luminous |
| | Phosphor | charged | analysis | analysis | analysis | analysis | efficiency | | retention | flux | flux |
| | compo- | amount | value | value | value | value | maintenance | | rate (%) | maintenance | maintenance |
| | sition | (mass %) | (mass %) | (mass %) | (mass %) | (ppm) | rate (%) | Resin | 1000 h | rate 1 (%) | rate 2 (%) |
| Reference | KSAF | 0 | — | 1.20 | 1.05 | — | 93.3 | Dimethyl | 42 | 98.9 | 95.8 |
| Example 6 | | | | | | | | silicone | | | |
| Example 15 | | 6 | 5.8 | 1.13 | 0.94 | 560 | 97.1 | resin 1 | 92 | 99.5 | 96.3 |
| Example 16 | | | 5.8 | 1.13 | 0.96 | 400 | 97.0 | | 92 | 99.9 | 96.7 |
| Example 17 | | | 6.0 | 1.13 | 0.97 | 1600 | 96.2 | | 91 | 97.3 | 97.3 |
| Example 18 | | | 5.8 | 1.13 | 0.96 | 430 | 97.9 | | 92 | 100.3 | 96.8 |

The SiO₂ analytical values of the fluoride phosphors of Examples 1 to 4 increased as the charging amount of SiO₂ was increased. In each case, the peak intensity ratio of the Kα rays of the element F measured by XRF in the fluoride phosphor of the Example was reduced to 8000 or less in relation to the peak intensity of the fluoride phosphors of Reference Example 1 and 2. From this, it is conceivable that the Kα rays of the F element are absorbed by the SiO₂ film, and it is conceivable that SiO₂ covers the surface of the fluoride particle as a film. In addition, from each absorption rate, the film thickness was calculated to be 0.13 μm or greater.

The quantum efficiency maintenance rates of the fluoride phosphors of Examples 1 to 3 were higher than that of the fluoride phosphor of Reference Example 1. In addition, in relation to the resin composition containing the fluoride phosphor of Reference Example 1, the resin compositions containing the fluoride phosphors of Examples 1 to 3 exhibited higher mass retention rates and more excellent durability of the resin compositions. Regarding durability of the resin composition, it is clear that in comparison to Example 1 in which the average thickness of the SiO₂ film was thin, in Examples 2 and 3 in which the average thickness of the SiO₂ film was thick, the mass retention rate of the resin compositions after 500 hours was further improved, and the durability of the resin compositions was further enhanced. Furthermore, in relation to Reference Example 2 in which the composition of the fluoride particles was changed, the fluoride phosphor of Example 4 in which the SiO₂ film was coated with the same composition exhibited a higher quantum efficiency maintenance rate in the durability evaluation, and the mass retention rate of the resin composition was also higher. That is, the same effect was obtained even with the fluoride particles having KSAF as the composition.

The light-emitting devices 1 in which the fluoride phosphors of Examples 1 to 3 were used exhibited a higher luminous flux maintenance rate 1 and more excellent durability in relation to the light-emitting device 1 that used the fluoride phosphor of Reference Example 1. From this, it is clear that with the light-emitting devices 1 as well, a light-emitting device that uses a fluoride phosphor coated with an SiO₂ film exhibits higher durability. In comparison to the light-emitting device 1 that used the fluoride phosphor of Reference Example 2, the light-emitting device 1 that used the fluoride phosphor of Example 4 also exhibited an improvement in durability, and the same effect was obtained even with the fluoride phosphor having KSAF as the composition. In a comparison of the light-emitting device 1 in which the fluoride phosphor of Example 2 was used and light-emitting device 1 in which the fluoride phosphor of Example 4 was used, the light-emitting device 1 in which was used the fluoride phosphor of Example 4, which used a fluoride phosphor having KSAF as the composition, had a 1% higher luminous flux maintenance rate 1 than the light-emitting device 1 in which was used the fluoride phosphor of Example 2, which used a fluoride phosphor having KSF as the composition.

An SEM image in which the fluoride phosphor obtained in Example 6 is observed with a scanning electron microscope is presented in FIG. 4. In FIG. 4, it is clear that the surface of the fluoride phosphor is smooth, and the silicon dioxide covering the fluoride particles is in the form of a continuous film and not in the form of particles. In addition, an SEM image in which the fluoride phosphor obtained in Example 8 is observed with a scanning electron microscope is presented in FIG. 6. From FIG. 6, it is clear that the silicon dioxide covering the fluoride particles is in the form of a continuous film and not in the form of particles, even with fluoride particles having KSAF as the composition.

An image obtained by observing, with a scanning electron microscope, a cross-section of the fluoride phosphor obtained in Example 6 is presented in FIG. 3. In FIG. 3, the gray portion corresponds to fluoride particles 2, the white portion corresponds to lanthanum phosphate 4, and the dark gray portion corresponds to the silicon dioxide 6. From this, it is clear that in the fluoride phosphor, the lanthanum phosphate 4 is adhered to the fluoride particles 2 and is further covered with the silicon dioxide 6. In addition, an image obtained by observing, with a scanning electron microscope, a cross-section of the fluoride phosphor obtained in Example 8 is presented in FIG. 5. In FIG. 5, the gray portion corresponds to fluoride particles 2, the white portion corresponds to lanthanum phosphate 4, and the dark gray portion corresponds to the silicon dioxide 6. From this, it is clear that the lanthanum phosphate 4 is adhered to the fluoride particles 2 and is further covered with the silicon dioxide 6.

The SiO₂ analysis values of the fluoride phosphors of Examples 5 to 11 were about the same as those of Examples 2 and 4. The measured average thicknesses of the SiO₂ films measured through image analysis of the cross-sectional SEM images of the fluoride phosphors of Examples 6 and 8 illustrated in FIGS. 3 and 5 were 0.50 μm and 0.44 μm, respectively. These average thicknesses are generally the same as the average film thicknesses calculated from XRF in Examples 2 and 4. From this, it was confirmed that the surface of the fluoride phosphor to which lanthanum phosphate was adhered was also covered with a SiO₂ film having about the same thickness. Therefore, it is thought that SiO₂ similarly covers the fluoride particles as a film even when the dropwise addition method, the dropwise addition time, and the stirring speed during the reaction are changed.

The TC analysis values of the fluoride phosphors of Examples 7 and 9 were higher than those of the fluoride phosphors of Reference Examples 3 and 4, and the presence of carbon was confirmed. Since this carbon is considered to be derived from the silane coupling agent, it is conceivable that a component derived from the silane coupling agent is adhered to the surface of the fluoride phosphor by subjecting the fluoride phosphor covered with SiO₂ to the silane coupling treatment.

The fluoride phosphors of Examples 5 to 7 exhibited higher quantum efficiency maintenance rates than the fluoride phosphor of Reference Example 3. In addition, in relation to the fluoride phosphor of Reference Example 3, the fluoride phosphors of Examples 5 to 7 exhibited higher mass retention rates and more excellent durability of the resin compositions. Regarding durability, it is clear that in comparison to Example 6, a higher quantum efficiency maintenance rate and further improved durability were exhibited by Example 7, which was subjected to the silane coupling treatment. It is thought that this was achieved because the surface of the SiO₂ film was made hydrophobic by the silane coupling treatment. In comparison to the fluoride phosphor of Reference Example 4 in which lanthanum phosphate was adhered to the fluoride particles, the fluoride phosphor of Example 8 covered with the SiO₂ film and having the same composition (KSAF) had a higher quantum efficiency maintenance rate in the durability evaluation and a higher mass retention rate of the resin composition and exhibited more excellent durability of the fluoride phosphor and the resin composition. Regarding durability, it is clear that in comparison to Example 8, a higher quantum efficiency maintenance rate and further improved durability were exhibited by Example 9, which was subjected to the silane coupling treatment. With respect to the fluoride particles having the second composition (KSAF), Example 8 to which lanthanum phosphate was adhered exhibited a higher quantum efficiency maintenance rate than that of Example 4 to which lanthanum phosphate was not adhered, and a higher effect was achieved by covering, with SiO₂, the surface of the phosphor to which lanthanum phosphate was adhered. That is, even with the fluoride phosphor to which lanthanum phosphate was adhered, an effect of improving durability was achieved by covering the fluoride phosphor with an SiO₂ film.

The light-emitting devices 1 in which the fluoride phosphors of Examples 5 to 7 were used exhibited higher luminous flux maintenance rates 1 and more excellent durability than the light-emitting device 1 that used the fluoride phosphor of Reference Example 3. It is clear that the luminous flux maintenance rate 1 and the durability of the light-emitting device 1 that used the fluoride phosphor of Example 7 subjected to the silane coupling treatment were further improved. A correlation is observed between the quantum efficiency maintenance rate of the fluoride phosphor and the luminous flux maintenance rate 1 of the light-emitting device 1. Furthermore, durability was improved by covering the fluoride phosphor with the SiO₂ film, and an effect of further improving the durability through the silane coupling treatment was obtained. In comparison with the light-emitting device 1 in which the fluoride phosphor of Reference Example 4 was used, further improvements in durability were observed in the light-emitting devices 1 that used the fluoride phosphors of Examples 8 and 9, and even with the fluoride particles having the second composition (KSAF) and to which lanthanum phosphate was adhered, an effect of improving durability was achieved by covering with an SiO₂ film.

When the sedimentation state of the phosphor was confirmed by observing the cross section of the light-emitting device 1, the phosphor was most sedimented in the light-emitting device of Example 7, which was subjected to the silane coupling treatment. In this case, it is conceivable that the affinity with the resin was improved by the silane coupling treatment, and as a result, the phosphor was more readily sedimented.

The fluoride phosphors of Examples 10 and 11 had higher quantum efficiency maintenance rates than the fluoride particles of Reference Example 1. In addition, in comparison to the fluoride particles of Reference Example 1, the fluoride phosphors of Examples 10 and 11 exhibited higher mass retention rates of the resin composition and more excellent durability of the resin composition. With the phenyl silicone resins 1 and 2, the mass retention rates were increased even with the fluoride particles of Reference Example 1, but in Examples 10 and 11, the mass retention rates were even higher. In the cases in which the dimethyl silicone resins 1 and 2 were used, the mass retention rate of the fluoride particles of Reference Example 1 was significantly reduced, but the mass retention rates of Examples 10 and 11 were high. In particular, the mass retention rate of Example 11 was higher, and a higher effect was achieved by covering, with the SiO₂ film, the surface of the phosphor to which lanthanum phosphate was adhered. With each of the resins, in comparison to the fluoride particles of Reference Example 1 having KSF as the composition, the durability of the resin composition was more excellent in Example 10 in which the fluoride particles having KSAF as the composition were covered with the SiO₂ film and in Example 11 in which the surface of the phosphor having lanthanum phosphate adhered thereto was covered with the SiO₂ film.

The fluoride phosphors of Examples 11 to 14 exhibited higher quantum efficiency maintenance rates than the fluoride phosphor of Reference Example 5. The mass retention rates of the resin compositions were also higher, and the durability of the resin compositions was excellent. The light-emitting devices 2 in which the fluoride phosphors of Examples 10 to 14 were used exhibited higher luminous flux maintenance rates 2 and more excellent durability than the light-emitting device 2 in which the fluoride phosphor of Reference Example 5 was used. In the light-emitting devices 2 in which the fluoride phosphors of Examples 11 and 12 were used, a fluoride phosphor in which the surface of the phosphor to which lanthanum phosphate was adhered was covered with SiO₂ was used, and these light-emitting devices 2 exhibited more excellent durability than the light-emitting device 2 in which the fluoride phosphor of Example 10 was used. This result seems to be due to the lanthanum phosphate improving the adhesiveness of the silica coating, resulting in a suppression of peeling of the coating layer, and the like. Furthermore, with the light-emitting device 2 in which the fluoride phosphor of Example 12 is used, it is conceivable that the affinity with the resin was improved by the silane coupling treatment, and thereby the phosphor was easily sedimented, and adherence with the resin was also improved, and as a result, an even higher effect was achieved. The light-emitting devices 2 that used the fluoride phosphors of Examples 13 and 14 in which the SiO₂ concentration was reduced exhibited more excellent durability than the light-emitting device 2 that used the fluoride phosphor of Example 10. It is conceivable that the reason for this is that the reduction in the SiO₂ concentration resulted in a suppression of cracking of the SiO₂ film, which also resulted in a suppression of contact with the external environment at locations of cracking. The light-emitting devices 2 that used the fluoride phosphors of Examples 13 and 14 in which fluoride particles having the second composition (KSAF) were covered with the SiO₂ film, and the light-emitting devices 2 that used the fluoride phosphors of Examples 11 and 12 in which the fluoride particles having the second composition (KSAF) and having lanthanum phosphate adhered thereto were covered with the SiO₂ film exhibited more excellent durability than the light-emitting device 2 that used the fluoride particles of Reference Example 3 having the KSF composition and having lanthanum phosphate adhered thereto.

The fluoride phosphors of Examples 15 to 18 exhibited higher quantum efficiency maintenance rates than the fluoride phosphor of Reference Example 6. The mass retention rates of these resin compositions were also increased, and the durability as a powder was excellent, and it is conceivable that the affinity with the resin was improved by the silane coupling treatment. In the durability evaluation 1, the light-emitting devices 2 that used the fluoride phosphors of Examples 15, 16, and 18 exhibited higher luminous flux maintenance rates 1 than the light-emitting device 2 that used the fluoride phosphor of Reference Example 6. Further, in the durability evaluation 2, the light-emitting devices 2 that used the fluoride phosphors of Examples 15 to 18 exhibited higher luminous flux maintenance rates 2 than the light-emitting device 2 that used the fluoride phosphor of Reference Example 6. The primary cause for this can be considered to be as follows, for example. In the silane coupling agent, a methoxy group or an ethoxy group is hydrolyzed to form a hydrogen bond with an —OH group on the surface of the phosphor, and is chemically bonded by heating. Therefore, it is difficult for the silane coupling agent to bind to a fluoride particle of the first composition (KSF) or the second composition (KSAF) with fewer —OH groups on the surface. On the other hand, it is conceivable that a large number of —OH groups are present on the surface of the fluoride phosphor in which the fluoride particles are covered with SiO₂, and thus the silane coupling agent is easily bonded, and the affinity with the resin is further improved, and thereby the effect as described above is achieved. In particular, the fluoride phosphors of Examples 15 to 18 have a second composition in which the surface of the phosphor to which lanthanum phosphate is adhered is covered with SiO₂. It is conceivable that the lanthanum phosphate further improved the adhesiveness of the SiO₂ film and further suppressed cracking, peeling, and the like of the coating layer, and thereby uniform bonding of the silane coupling agent was facilitated, and affinity with the resin was improved.

The fluoride phosphor according to the present disclosure can be used particularly in a light-emitting device in which a light-emitting diode is used as an excitation light source, and for example, can be suitably used in a light source for illumination, a light source for application in an LED display or liquid crystal backlight, a traffic signal, an illuminated switch, various sensors, various indicators, and a compact strobe.

The disclosures of the Japanese Patent Application No. 2021-091754 (filed on May 31, 2021), the Japanese Patent Application No. 2021-130074 (filed on Aug. 6, 2021), the Japanese Patent Application No. 2021-141629 (filed on Aug. 31, 2021), and the Japanese Patent Application No. 2022-083514 (filed on May 23, 2022) are incorporated herein by reference in their entirety. All publications, patent applications, and technical standards described in the present specification are incorporated herein by reference to the same extent as a case in which the incorporation by reference of each individual publication, patent application, and technical standard is specifically and individually indicated to be incorporated by reference.

1. A fluoride phosphor comprising a fluoride particle and an oxide covering at least a portion of a surface of the fluoride particle,
the oxide comprising at least one element selected from the group consisting of Si, Al, Ti, Zr, Sn, and Zn, and a content of the oxide being in a range from 2 mass % to 30 mass % in relation to the fluoride phosphor, and
the fluoride particle having a composition comprising an element M, an alkali metal, Mn, and F, the element M comprising at least one element selected from the group consisting of Group 4 elements, Group 13 elements, and Group 14 elements, wherein, when a number of moles of the alkali metal is 2, a number of moles of Mn is in a range greater than 0 and less than 0.2, a number of moles of the element M is in a range greater than 0.8 and less than 1, and a number of moles of F is in a range greater than 5 and less than 7.

2. The fluoride phosphor according to claim 1, wherein the fluoride particle has a composition comprising Si and/or Ge as the element M, and when the number of moles of the alkali metal is 2, a total number of moles of Si, Ge, and Mn is in a range from 0.9 to 1.1.

3. The fluoride phosphor according to claim 1, wherein the fluoride particle has a composition represented by Formula (1) below: 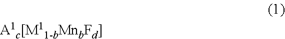
where in Formula (1), A¹ comprises at least one selected from the group consisting of Li, Na, K, Rb and Cs; M¹ at least comprises at least Si and/or Ge, and may further comprise at least one element selected from the group consisting of Group 4 elements and Group 14 elements; b satisfies 0<b<0.2, c is an absolute value of a charge of the [M¹_{1-b}Mn_{b}F_{d}] ion, and d satisfies 5<d<7.

4. The fluoride phosphor according to claim 1, wherein the fluoride particle has a composition comprising Si and Al as the element M, and when the number of moles of the alkali metal is 2, a total number of moles of Si, Al, and Mn is in a range from 0.9 to 1.1, and a number of moles of Al is in a range greater than 0 and 0.1.

5. The fluoride phosphor according to claim 1, wherein the fluoride particle has a composition represented by Formula (2) below: 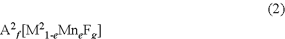
where in Formula (2), A² comprises at least one selected from the group consisting of Li, Na, K, Rb, and Cs; M² comprises at least Si and Al, and may further comprise at least one element selected from the group consisting of Group 4 elements, Group 13 elements, and Group 14 elements; e satisfies 0<e<0.2, f is an absolute value of a charge of the [M²₁₋ₑMnₑF_{g}] ion, and g satisfies 5<g<7).

6. The fluoride phosphor according to claim 1, wherein the oxide contains silicon.

7. The fluoride phosphor according to claim 1, wherein an average thickness of the oxide is in a range from 0.1 μm to 1.8 μm.

8. The fluoride phosphor according to claim 1, wherein in X-ray fluorescence elemental analysis, a ratio of a peak intensity of Kα rays of the element F in the fluoride phosphor to a peak intensity of Kα rays of the element F in the fluoride particles is 80% or less.

9. The fluoride phosphor according to claim 1, wherein a rare earth phosphate containing at least one rare earth element selected from the group consisting of La, Ce, Dy and Gd is disposed on a surface of the fluoride particle, and the oxide covers the fluoride particle with the rare earth phosphate interposed therebetween.

10. The fluoride phosphor according to claim 9, wherein the rare earth phosphate comprises lanthanum.

11. The fluoride phosphor according to claim 9, wherein a content percentage of the rare earth phosphate is in a range from 0.1 mass % to 20 mass % as a content percentage of the rare earth element.

12. A method for manufacturing a fluoride phosphor, the manufacturing method comprising:
preparing a fluoride particle having a composition comprising an element M, an alkali metal, Mn, and F, the element M comprising at least one element selected from the group consisting of Group 4 elements, Group 13 elements, and Group 14 elements, wherein when a number of moles of the alkali metal is 2, a number of moles of Mn is in a range greater than 0 and less than 0.2, a number of moles of the element M is a range greater than 0.8 and less than 1, and a number of moles of F is in a range greater than 5 and less than 7; and
causing the prepared fluoride particle and a metal alkoxide comprising at least one element selected from the group consisting of Si, Al, Ti, Zr, Sn, and Zn to come into contact with each other in a liquid medium thereby covering at least a portion of a surface of the fluoride particle with an oxide derived from the metal alkoxide at an amount in a range from 2 mass % to 30 mass % relative to the fluoride phosphor.

13. A method for manufacturing a fluoride phosphor, the manufacturing method comprising:
preparing a fluoride particle having a composition comprising an element M, an alkali metal, Mn, and F, the element M comprising at least one element selected from the group consisting of Group 4 elements, Group 13 elements, and Group 14 elements, wherein, when a number of moles of the alkali metal is 2, a number of moles of Mn is in a range greater than 0 and less than 0.2, a number of moles of the element M is a range greater than 0.8 and less than 1, and a number of moles of F is in a range greater than 5 and less than 7;
causing the prepared fluoride particle, rare earth ions including at least one type selected from the group consisting of La, Ce, Dy, and Gd, and phosphate ions to come into contact with each other in a liquid medium thereby obtaining a fluoride particle to which a rare earth phosphate is adhered; and
causing the fluoride particle to which the rare earth phosphate is adhered and a metal alkoxide comprising at least one element selected from the group consisting of Si, Al, Ti, Zr, Sn, and Zn to come into contact with each other in a liquid medium thereby covering at least a portion of a surface of the fluoride particle to which the rare earth phosphate is adhered with an oxide derived from the metal alkoxide at an amount in a range from 2 mass % to 30 mass % relative to the fluoride phosphor.

14. The manufacturing method according to claim 12, wherein the prepared fluoride particle has a composition comprising at least Si and/or Ge as the element M, and when a number of moles of the alkali metal is 2, a total number of moles of Si, Ge, and Mn is in a range from 0.9 to 1.1.

15. The manufacturing method according to claim 14, wherein the prepared fluoride particle has a composition represented by Formula (1) below: 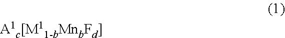
where in Formula (1), A¹ comprises at least one selected from the group consisting of Li, Na, K, Rb and Cs; M¹ comprises at least Si and/or Ge, and may further comprise at least one element selected from the group consisting of Group 4 elements and Group 14 elements; b satisfies 0<b<0.2, c is an absolute value of a charge of the [M¹_{1-b}Mn_{b}F_{d}] ion, and d satisfies 5<d<7.

16. The manufacturing method according to claim 12, wherein the prepared fluoride particle has a composition comprising Si and Al as the element M, and when a number of moles of the alkali metal is 2, a total number of moles of Si, Al, and Mn is in a range from 0.9 to 1.1, and a number of moles of Al is in a range greater than 0 and 0.1.

17. The manufacturing method according to claim 16, wherein the prepared fluoride particle has a composition represented by Formula (2) below: 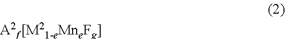
where in Formula (2), A² comprises at least one selected from the group consisting of Li, Na, K, Rb, and Cs; M² comprises at least Si and Al, and may further comprise at least one element selected from the group consisting of Group 4 elements, Group 13 elements, and Group 14 elements; e satisfies 0<e<0.2, f is an absolute value of the charge of the [M²₁₋ₑMnₑF_{g}] ion, and g satisfies 5<g<7).

18. The manufacturing method according to claim 12, further comprising performing a silane coupling treatment after at least a portion of the surface of the fluoride particle has been covered with the oxide derived from the metal alkoxide.

19. The manufacturing method according to claim 12, wherein the metal alkoxide brought into contact in the liquid medium includes at least one selected from the group consisting of tetramethoxysilane, tetraethoxysilane, and tetraisopropoxysilane.

20. A light-emitting device comprising:
a fluorescent member comprising a fluoride phosphor described in claim 1 and a resin; and
a light-emitting element having a light emission peak wavelength in a wavelength range from 380 nm to 485 nm.
